(19) United States
(12) Patent Application Publication
(10) Pub. No.: US 2025/0372536 A1
(43) Pub. Date: Dec. 4, 2025

(54) BACK-SIDE WARPAGE CONTROL LAYER TO IMPROVE BONDING BULGE / NON-BONDING

(71) Applicant: Taiwan Semiconductor Manufacturing Co., Ltd., Hsinchu (TW)

(72) Inventors: Chen-Shien Chen, Zhubei City (TW); Chi-Yen Lin, Tainan City (TW); Feng-Chang Hsu, Hsinchu County (TW); Hsu-Hsien Chen, Hsinchu (TW); Wu-An Weng, Hsinchu (TW)

(21) Appl. No.: 18/732,256

(22) Filed: Jun. 3, 2024

(51) Int. Cl. H01L 23/00; H01L 23/48; H01L 25/00; H01L 25/065

(52) U.S. Cl. CPC H01L 23/562; H01L 23/48; H01L 24/08; H01L 24/80; H01L 25/0652; H01L 25/50; H01L 2224/08145; H01L 2224/80895; H01L 2224/80896

(57) ABSTRACT

A semiconductor device and method of manufacturing are disclosed. The semiconductor device includes a first die having a plurality of external electrical connections on a first side; a first warpage control layer disposed on a second side of the first die opposite the first side, where the first warpage control layer limits curvature of the first die while the first die is unsupported on the first side; a second die disposed on a first side on the first warpage control layer opposite the first die, where the second die is electrically connected to the first die; and a second warpage control layer disposed on a second side of the second die opposite the first side, where the second warpage control layer limits curvature of the second die while the second die is unsupported on the first side.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

System on Integrated Chips (SoIC) has been developed to integrate passive and active chips into system on chips (SoC) packages to meet ever-increasing market demands for higher computing efficiency, wider data bandwidth, higher functionality packaging density, lower communication latency, and lower energy consumption per bit of data. However, as heterogeneous chips are stacked in a three-dimensional (3D) logic-on-logic or memory-on-logic chiplet stacking technology platform, a relatively high incident of non-bonding or bonding bulges has been noted at the back side silicon interface of stacked chiplets. This non-bonding or introduction of bonding bulges in stacked chiplets is due to chip curvature after singulation and during pick-and-place operations where the chiplets are unsupported. If too much curvature is introduced into the chiplets, the chiplet will not straighten sufficiently during the timing limitations for successfully bonding stacked chips together. Accordingly, an improved fabrication method is needed to reduce or eliminate bonding bulge and/or non-bonding at the backside silicon interface of vertically stacked chiplets.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 8 illustrate the singulation, preparation, and application of a first warpage control layer on a set of first dies, in accordance with some embodiments;

FIG. 9 illustrates the transition of known good first dies to a first reconstruction wafer in accordance with some embodiments;

FIGS. 10A through 10D illustrates the result of a switch process bonding the first dies to a first carrier, in accordance with some embodiments;

FIGS. 11-18 illustrate the singulation, preparation, and application of a second warpage control layer on a set of second dies, in accordance with some embodiments;

FIG. 19 illustrates the transition of known good second dies to a second reconstruction wafer in accordance with some embodiments;

FIG. 20 illustrates the result of a second switch process bonding the second dies to the first carrier, in accordance with some embodiments;

FIGS. 21-27 illustrate the completion and singulation of an integrated circuit package comprising the first dies and the second dies in a vertical stack, in accordance with some embodiments;

FIG. 28 illustrates the formation of a flip-chip device with the integrated circuit package comprising the first dies and the second dies in a vertical stack, in accordance with some embodiments; and

FIG. 29 illustrates the formation of a chip-on-wafer-on-substrate (CoWoS) device with the integrated circuit package comprising the first dies and the second dies in a vertical stack, in accordance with some embodiments.

### DETAILED DESCRIPTION OF ILLUSTRATIVE EMBODIMENTS

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which one or more dies are vertically bonded. A warpage control layer is applied to the backside substrate of each die to facilitate die-to-die bonding and to reduce or eliminate bonding bulge, de-bonding, non-bonding, and the like. However, the embodiments presented herein are intended to be illustrative and are not intended to limit the embodiments to the precise descriptions as discussed. Rather, the embodiments discussed may be incorporated into a wide variety of implementations, and all such implementations are fully intended to be included within the scope of the embodiments.

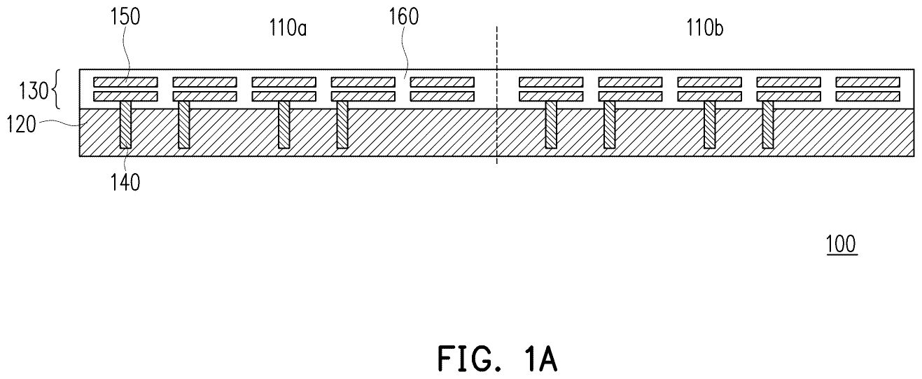

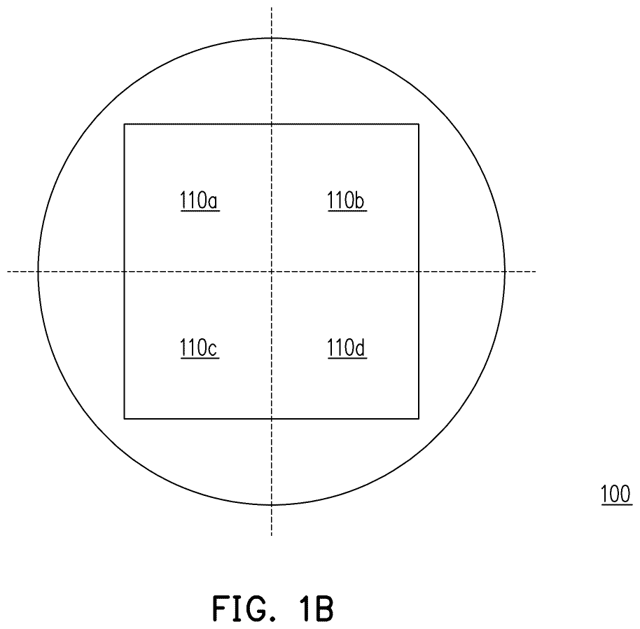

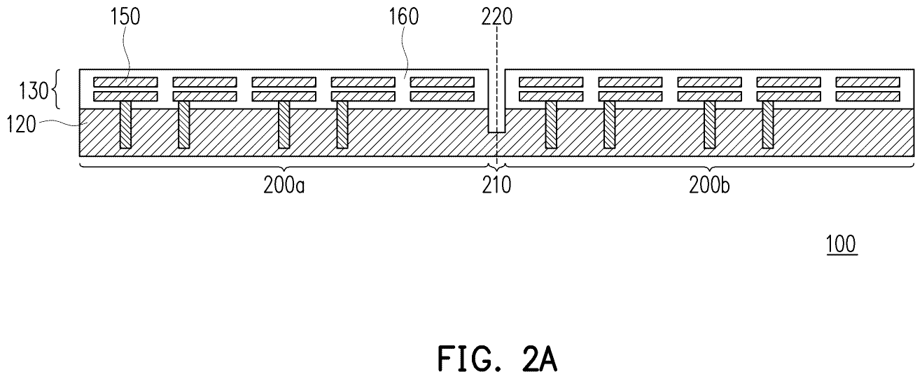

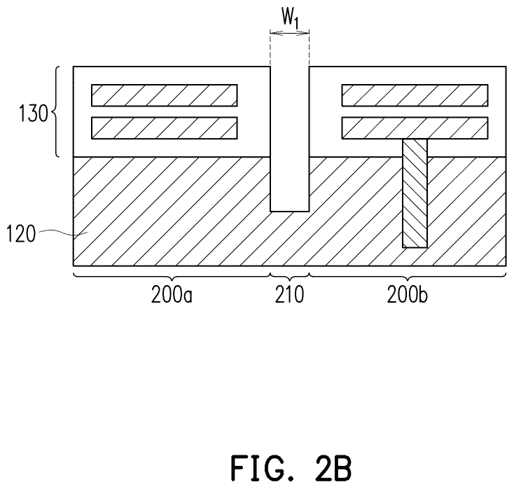

With reference now to FIGS. 1A and 1B, there is illustrated a first wafer 100 that has a plurality of die regions (110a, 110b, and the like), in which first dies 200 formed in/on it, in accordance with some embodiments. FIG. 1A is a cross-sectional view of the dies formed on first wafer 100 according to some embodiments. FIG. 1B is an overhead view of the first wafer 100 according to some embodiments. As shown in FIG. 1A, in some embodiments, a number of first dies 200 (see FIG. 2) may be fabricated as part of a larger first wafer 100 or panel form fabrication process having multiple die regions such as first die regions 110a and 110b (collectively 110). For example, FIG. 1B illustrates a circular shaped wafer 100 with four first die regions 110a through 110d. In the embodiment shown, four first dies are included on the first wafer 100 allowing for four first dies to be fabricated on a single wafer and singulated. Fewer or more die regions may be utilized on a single wafer or panel in other embodiments.

In the particular embodiment illustrated in FIG. 1A, the first dies fabricated in first die regions 110a and 110b comprise a first substrate 120 and a first interconnect structure 130. The first substrate 120 may be a bulk silicon or other semiconductor material wafer, a silicon-on-insulator (SOI) wafer, or the like. The first substrate 120 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The first substrate 120 has an active surface (e.g., the surface facing upward) and an inactive surface (e.g., the surface facing downward). Devices are at the active surface of the first substrate 120. The devices may be active devices (e.g., transistors, diodes, etc.), capacitors, resistors, etc. The inactive surface may be free from devices. The substrate may also contain one or more through silicon vias (TSVs) 140.

The first interconnect structure 130 is over the active surface of the first substrate 120, and is used to electrically connect the devices of the first substrate 120 to form one or more integrated circuits. The first interconnect structure 130 may include metallization pattern(s) 150 in one or more the dielectric layer(s) 160. Acceptable dielectric materials for the dielectric layers 160 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, and any suitable means of forming, growing, or depositing the dielectric layers 160 may be used.

The metallization patterns 150 may include conductive vias and/or conductive lines to interconnect the devices of the first substrate 120. The metallization patterns 150 may be formed of a conductive material, such as a metal, such as copper, cobalt, aluminum, gold, combinations thereof, or the like. The metallization patterns 150 may be formed by a damascene process, such as a single damascene process, a dual damascene process, or the like. The first interconnect structure 130 may further include metal pads (e.g., aluminum pads, copper pads, or the like) (not shown), which are connected to a top-most metallization pattern 150 of the first interconnect structure 130 through one or more passivation layers. An additional insulating layer (e.g., a passivation layer) may be formed around the metal pads to provide a planar surface on which to form further overlaying features (e.g., bond pads and an insulating bonding layer).

In some embodiments the first interconnect structure 130 may include optical components such as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. Devices at the active surface of the first substrate 120 may be used in conjunction with optical components in the first interconnect structure 130 to complete the optical components.

FIG. 2A illustrates the start of a multi-step singulation of first dies 200 in accordance with some embodiments. In some embodiments, an etching process is used to partially singulate first die 200a from first die 200b (collectively first dies 200). In some embodiments, the trenches 210 are formed with combination of photolithography and etching processes. For example, the trenches may be formed in a plasma dicing process along the scribe lines 220. The plasma dicing process may include forming a patterned mask over the interconnect structure. The patterned mask may be a photomask that is deposited in a spin-on process over the first interconnect structure 130 and patterned by lithography (e.g., exposure and development) to define openings that expose the first interconnect structure 130 in the scribe line 220. The plasma dicing process etches portions of the first interconnect structure 130 and the first substrate 120 through the patterns (e.g., openings) in the patterned mask. The trenches 210 may extend through the first interconnect structure 130 to a desired depth into the first substrate 120. However, the trenches 210 may not extend fully through the first substrate 120, and lower portions of the first substrate 120 may remain to connect the first dies 200 together in the first wafer 100. In some embodiments, the depth of the trenches 210 may be between 1 micrometer (μm) and 750 μm into the first substrate 120.

In some embodiments the etching process may be performed in multiple steps and may utilize a plasma dry etch process and/or a reactive ion etch (RIE). For example, a first reactive ion etch using reactive gases such as CF₄, C₄F₈, CHF₃, or CH₃F may be performed to preferentially etch through the dielectric layers 160 of the first interconnect structure 130. A second reactive ion etch may then be performed using gases such as SF₆ or NF₃ to preferentially etch the first substrate 120. The depth of the etch may be controlled by varying the timing of the etching process, among other process parameters. In some embodiments a third etch may be performed where the third etch is a wet etch to cure any surface defects in the first dies 200 resulting from a dry etching process. In some embodiments, the RIE uses an argon-based plasma, an oxygen-based plasma, a nitrogen-based plasma, or the like. However, any suitable method of etching trenches to singulate the first dies 200 may be utilized.

FIG. 2B is an enlarged partial view of FIG. 2a. In some cases, the width (W₁) of the trench formed by etching between the each of the first dies 200 may be between 0.1 μm and 1000 μm. In some embodiments the width (W₁) of the trench may be narrow enough to preclude later deposition in the trench. In some embodiments, the width (W₁) of the trench may be 8 μm or less to limit deposition in the trench.

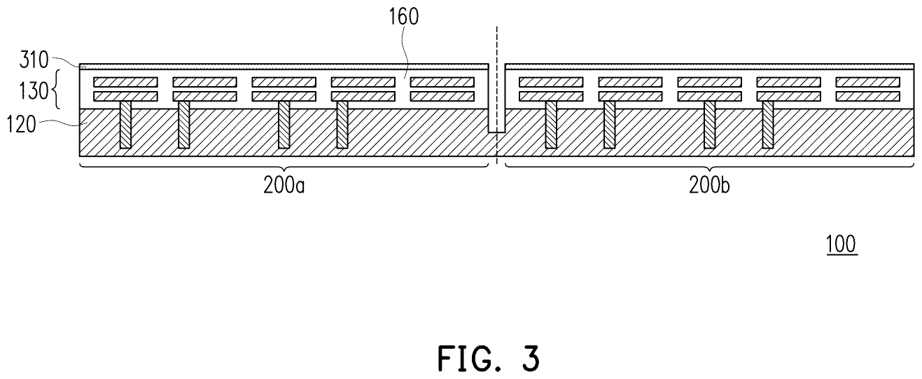

FIG. 3 illustrates the formation of a protective layer 310 over the first interconnect structure 130 of the first dies 200 according to some embodiments. In some embodiments, a surface treatment may be performed in the trenches 210 prior to forming the protective layer 310. In some embodiments, the surface treatment is a fluorine-based treatment, such as a wet cleaning process using a fluorine-comprising solution, a fluorine-based plasma process, or the like. In some embodiments, the fluorine-based plasma process may be performed at a temperature in a range of 25° C. to 500° C. and at a pressure of 0 Torr to 1.316×10−3 Torr (one atmosphere). Other treatments that form hydrophobic surfaces may be applied in other embodiments. The surface treatment makes the surfaces of the trenches 210 hydrophobic so that a subsequently formed protective layer 310 can be deposited over the first interconnect structure 130 without being significantly deposited in the trenches 210. When the surface treatment is a fluorine-based treatment, the resulting surface regions may likewise comprise fluorine and be referred to as a fluorinated protection layer. For example, surface regions may comprise 5 weight % (wt%) or more fluorine, which advantageously results in hydrophobic surfaces in the trenches 210. The surface regions may further comprise carbon, oxygen, silicon, nitrogen, or a combination thereof. The specific material composition of the surface regions may depend on a material of the first interconnect structure 130 and/or first substrate 120 on which the surface regions are formed. For example, portions of the surface regions on the first substrate 120 may comprise fluorine and silicon while portions of the surface regions on the first interconnect structure 130 may comprise fluorine in combination with carbon, oxygen, nitrogen and/or silicon.

The surface treatment may be performed while a patterned mask covers the first interconnect structure 130. As a result, the surface regions can be selectively formed in the trenches 210 without blanket forming the surface regions over the first interconnect structure 130. For example, after the surface treatment, top surface of the first interconnect structure 130 may remain hydrophilic so that protective layer 310 can be deposited thereon. After the surface treatment, the patterned mask may be removed. For example, when the patterned mask is a photomask, the patterned mask may be stripped away with an ashing process.

A protective layer 310 may then be deposited over first interconnect structure 130. In some embodiments, the protective layer 310 is a back side anti-reflective coating (BARC) layer that is deposited by a spin-on process, or the like. As a result of the surface treatment and the hydrophobic surface regions, the protective layer 310 may not be significantly deposited within the trenches 210. Keeping the protective layer 310 from being deposited in the trenches 210 achieves advantages such as reduced manufacturing defects and improved yield. In other embodiments, the protective layer 310 may be a photoresist, or other suitable material, deposited or formed using suitable application processes.

In some embodiments, the protective layer 310 may be between 1 nm and 100 nm thick. A planarization process (e.g., a chemical mechanical polish (CMP) or the like) may be performed such that top surfaces of the protective layer 310 is coplanar (within process variations). In some embodiments, a spin on process may be used to control uniformity of the protective layer 310.

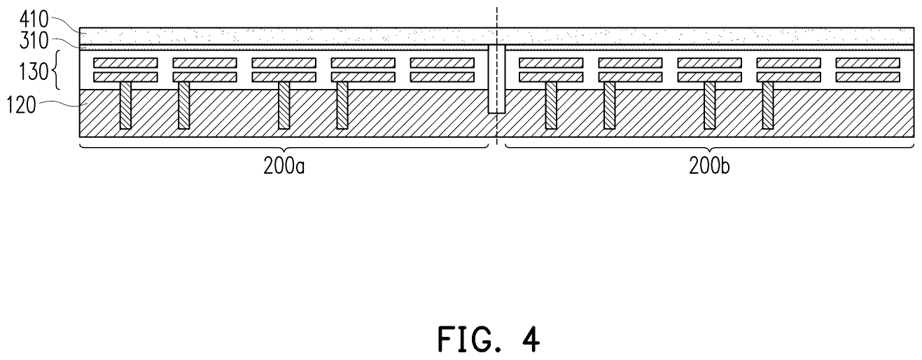

FIG. 4 illustrates the application of a back-side grinding (BG) tape according to some embodiments. As shown, BG tape 410 is adhered to the first wafer 100, such as to a top surface of the protective layer 310. The BG tape 410 supports the first wafer 100 during the first dies 200 final singulation and following preparation. The protective layer 310 acts as an intermediary, buffer between the first wafer 100 and the BG tape 410. For example, the protective layer 310 protects a top surface of the first interconnect structure 130 from direct contact with the BG tape 410, reducing the risk of damage to the first interconnect structure 130.

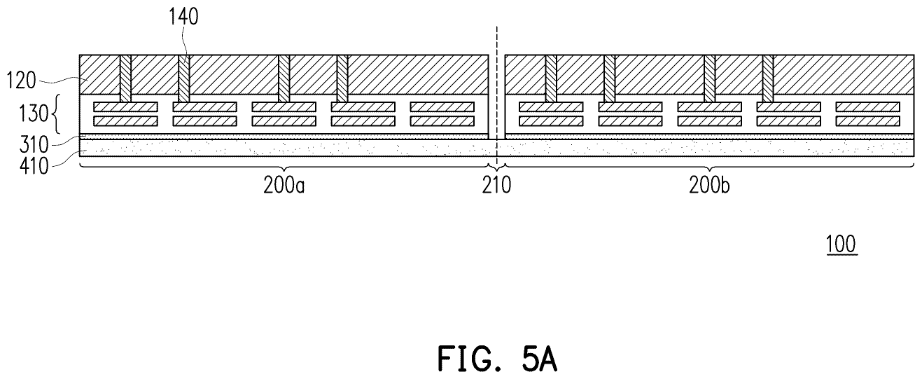

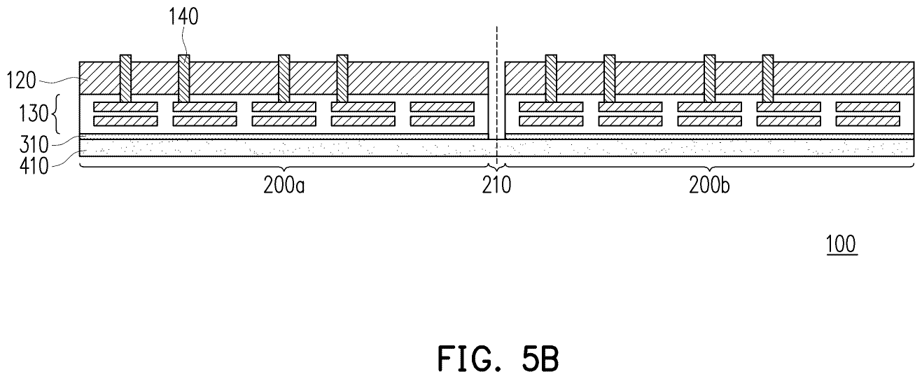

FIG. 5A illustrates the thinning of the first substrate 120 of the first dies 200 according to some embodiments. As shown, the first wafer 100 may be flipped over such that the BG tape 410 is generally oriented on the bottom side of the first wafer 100. The first substrate 120 may then be thinned until the TSVs 140 have been exposed and the connected portions of the first substrate 120 removed, thereby fully singulating first dies 200. In an embodiment, the first substrate 120 may be thinned using, e.g., a CMP process, a grinding process, slicing, or the like. Further, once exposed, the TSVs 140 may be further exposed using, e.g., one or more etching processes, such as a wet etch process in order to recess the first substrate 120 so that the TSVs 140 extend out of the first substrate 120 (as shown in FIG. 5B). In other embodiments, first dies 200 may be singulated using a saw process, solely or in combination with an etching process such as described above.

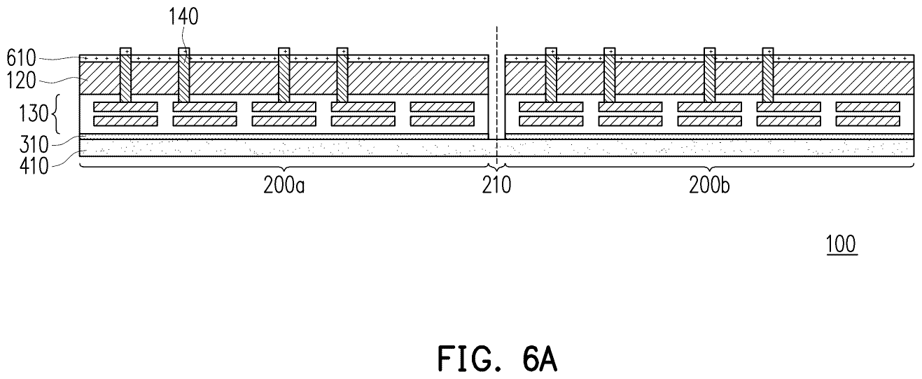

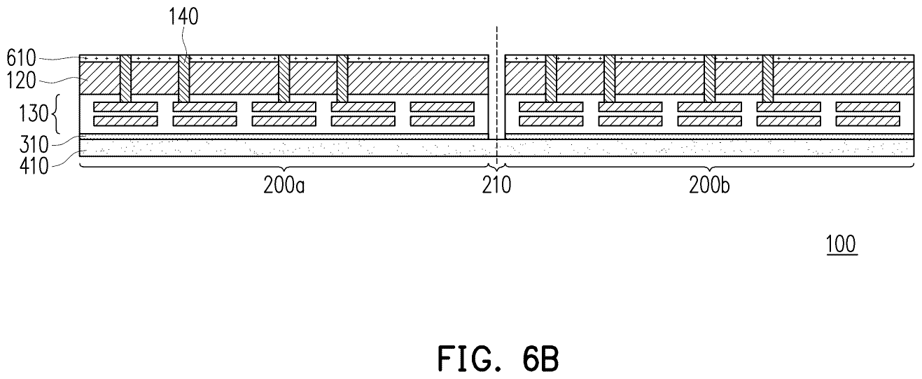

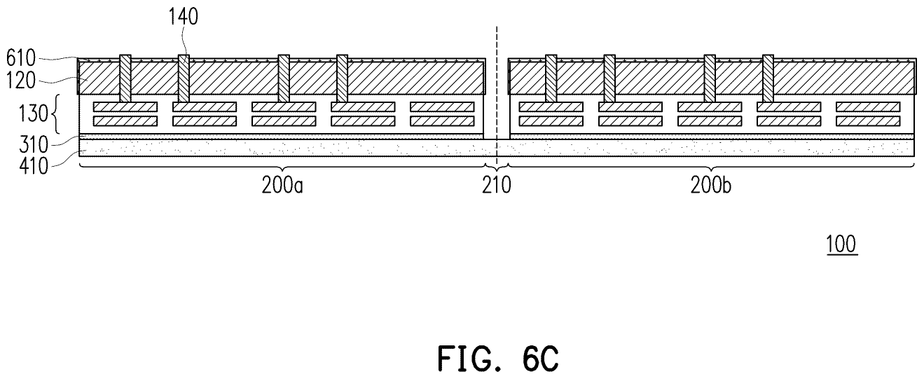

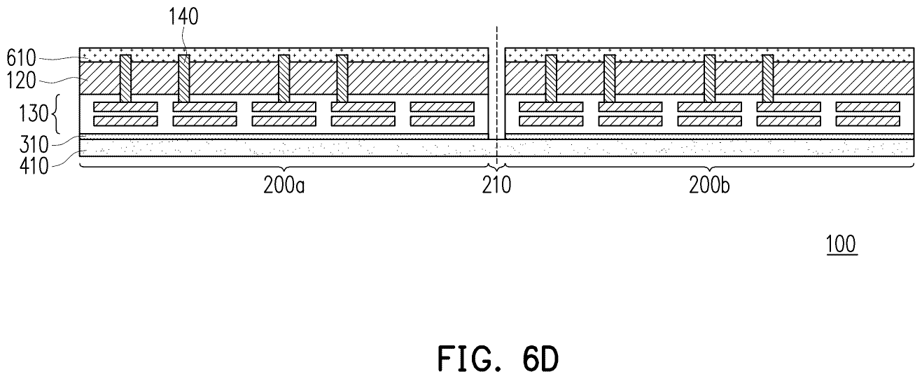

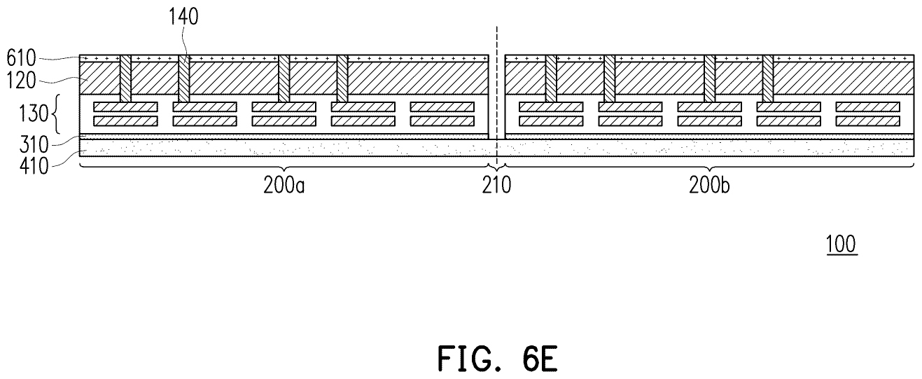

FIG. 6A illustrates a first warpage control layer 610 applied to the thinned first substrate 120 on the back side of the first dies 200 according to some embodiments. In some embodiments the first warpage control layer 610 may be silicon oxide, silicon nitride, silicon oxynidtride, silicon carbide, organic material, or some other dielectric material. The first warpage control layer 610 may be deposited on the first substrate 120, for example, by spin coating, lamination, chemical vapor deposition (CVD), atomic layer deposition (ALD), physical vapor deposition (PVD), high-density plasma chemical vapor deposition (HDPCVD), thermal oxidation, a combination thereof, and/or the like. A planarization process (e.g., a chemical mechanical polish (CMP) or the like) may be performed such that top surfaces of the first warpage control layer 610 is coplanar (within process variations). In embodiments where the first substrate 120 has been recessed to expose portions of the TSVs 140, the planarization process may be performed such that the top surfaces of the first warpage control layer 610 and TSVs 140 are coplanar (within process variations) (for example, as shown in FIG. 6B).

In some embodiments, due to the small width of trenches 210 between first dies 200 (for example less than approximately 8 μm), as well as selected process conditions, process gases can be substantially precluded from interacting with the etched sidewalls of first dies 200. For example, a bias power of 1 to 5 kilowatts (kW) may be used to increase vertical bombardment and limit formation of the first warpage control layer 610 on the sidewalls of the first dies 200. In embodiments where the surface treatment is performed in the trenches 210 prior to forming the protective layer 310, the surface treatment may further prevent formation of the first warpage control layer 610 on the etched sidewalls of the first dies 200.

In other embodiments, for example as shown in FIG. 6C, the first warpage control layer 610 may encapsulate portion, or all, of the sidewall of the first dies 200. For example, where the first warpage control layer 610 is a silicon oxide layer formed through thermal oxidation, the first warpage control layer 610 will form along all exposed portions of the first substrate 120 where that is composed of silicon. In some embodiments, the TSVs 140 may protrude beyond the first warpage control layer 610 after formation.

FIG. 6D and 6E illustrate an alternative embodiment for forming the first warpage control layer 610. In FIG. 6D, a thick conformal deposition method is used to deposit the first warpage control layer 610. Subsequently a wet etch, for example using hydrofluoric acid, may be used to reduce the thickness of the first warpage control layer 610 and expose the top portions of the TSVs 140 as shown in FIG. 6E. Other methods of leveling the first warpage control layer 610 and exposing the TSVs 140, for example through the combination of photolithography and etching processes, may be used to form the first warpage control layer 610 and are foreseen.

In some embodiments the first warpage control layer 610 is between 10 angstroms (Å) and 1000 Å thick. In some embodiments, the first warpage control layer 610 may include multiple layers of silicon oxide, silicon nitride, silicon oxynidtride, silicon carbide, organic material, or some other dielectric material deposited or formed using the methods described above, or other suitable processing techniques. Once formed, the first warpage control layer 610 adds rigidity to the first dies 200 and limits the amount of curvature that first dies 200 will experience during later pick-and-place operations (for example, as described below). By limiting the curvature introduced in the die, the die may already be, or have time to straighten within the timing parameters for bonding. For example, a specific moisture content or wetness of the die may be a limiting factor in production, where the die dries over time. By reducing the amount of curvature introduced, the die is more likely to straighten to within tolerances (if outside of those after the pick-and-place) and non-bonding or bonding bulges can be reduced. Accordingly, higher manufacturing yields, lowered production costs, lowered material waste, and increased manufacturing efficiencies are realized.

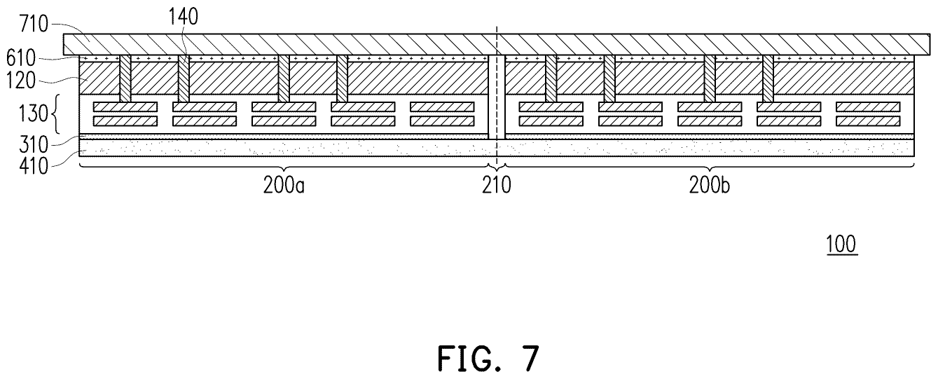

FIG. 7 illustrates application of a dicing tape 710 to the first dies 200 according to some embodiments. The dicing tape supports the first dies 200 and retains the wafer integrity of the first wafer 100 during the completion of the first dies 200 preparation process. In some embodiments, the dicing tape may be in contact with top metal portions of the TSVs 140 as well as the first warpage control layer 610.

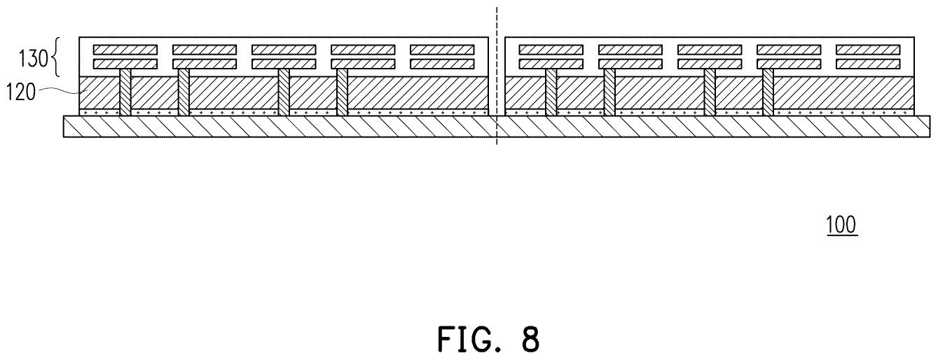

FIG. 8 illustrates removal of the BG tape 410 and reorientation of the wafer according to some embodiments. As shown, the wafer is flipped and the BG tape 410 removed to expose the protective layer 310. The protective layer 310 may also be removed at this point, as shown in FIG. 8, or after the pick-and-place operation described below, but prior to formation of the first bonding layer 1030. In some embodiments, a further planarization process, such as CMP, may be performed on interconnect layer 130 to remove residue and cure imperfections (within process parameters) caused by removal of the BG tape 410.

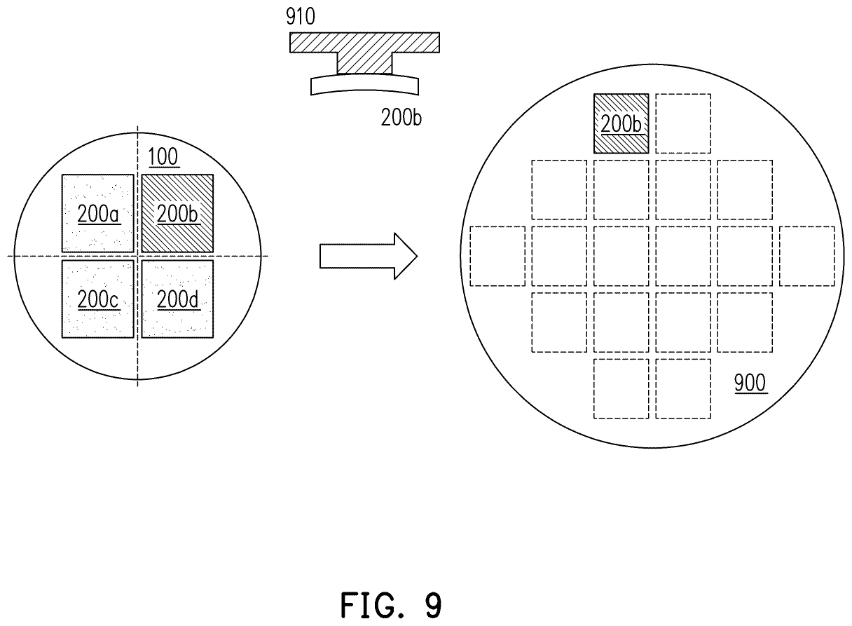

FIG. 9 illustrates placement of known good first dies 200 from the first wafer 100 on to a first reconstruction wafer 900 or film according to some embodiments. Prior to the singulation of the wafer using the etching process described above, the first wafer 100 may be tested to identify each known good die in the first dies 200. After the singulation process a pick-and-place device may be used to move each known good first die 200 to the first reconstruction wafer 900. In some embodiments, the reconstruction wafer may comprise a release film. Because the first dies 200 are not flipped during the pick-and-place process, the first warpage control layer 610 of each first die 200 will be closest to the first reconstruction wafer 900.

For the sake of simplicity, only one known good first die 200 of the first wafer 100 is shown transferred to the first reconstruction wafer 900. However, no limitation is intended on the number of known good first dies 200 singulated from the first wafer 100. Similarly, no limitations are intended on the number of known good first dies 200 that may be transferred from the first wafer 100 to the first reconstruction wafer 900. Design requirements, space constraints of the first wafer 100 and the first reconstruction wafer 900 will factor in, however.

It is during this movement, from the first wafer 100 supported by the dicing tape 710, to the first reconstruction wafer 900, the first die (e.g., 200b) will be held by the pick-and-place machine 910, but unsupported on the bottom of the first die 200. Accordingly, the natural tendency of first die is to warp downward introducing curvature into the first die 200. As addressed above, warpage control layer 610 will significantly reduce or eliminate such warpage.

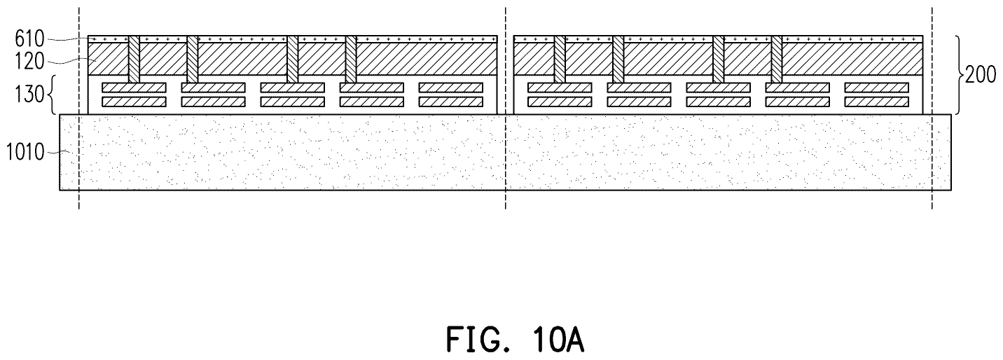

FIG. 10A illustrates the resulting structure for a single first dies 200 on a first carrier substrate 1010 after a switch process, according to some embodiments. During the switch process the first reconstruction wafer 900, with the associated known good first dies 200, is attached to a first carrier substrate 1010 such that the first warpage control layer 610 on each first die 200 is furthest from the first carrier substrate 1010. Any suitable method of attaching the first carrier substrate 1010 may be used. The first reconstruction wafer 900 may then be de-bonded/released from the known good first dies 200 revealing the first warpage control layer 610 on each known good first die 200. In embodiments, for example where metallic portions of TSVs 140 are substantially coplanar (within process parameters), the metallic portions of TSVs 140 will also be revealed.

The first carrier substrate 1010 may be a bulk silicon or other semiconductor material wafer, a silicon-on-insulator (SOI) wafer, or the like. The first carrier substrate 1010 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The first carrier substrate 1010 may also contain one or more TSVs (not shown).

FIG. 10B illustrates filling of the gaps between first dies 200 on the first carrier substrate, according to some embodiments. As shown, a first encapsulant 1020 is formed over the first carrier substrate 1010, and over and surrounding the first dies 200 In some embodiments, the first encapsulant 1020 may comprise one or more layers of non-photo-patternable insulating materials such as silicon nitride, silicon oxide, phosphosilicate glass (PSG), borosilicate glass (BSG), boron-doped phosphosilicate glass (BPSG), a combination thereof, or the like, and may be formed using CVD, PVD, ALD, a spin-on coating process, a combination thereof, or the like. In other embodiments, the first encapsulant 1020 may comprise one or more layers of photo-patternable insulating materials such as polybenzoxazole (PBO), polyimide (PI), benzocyclobutene (BCB), a combination thereof, or the like, and may be formed using a spin-on coating process, or the like. Such photo-patternable insulating materials may be patterned using similar photolithography methods as a photoresist material. In other embodiments, the first encapsulant 1020 may comprise a molding compound, such as an epoxy, a resin, a moldable polymer, a combination thereof, or the like. The molding compound may be applied while substantially liquid, and then may be cured through a chemical reaction, such as in an epoxy or resin. In other embodiments, the molding compound may be an ultraviolet (UV) or thermally cured polymer applied as a gel or malleable solid capable of being disposed around and between the first dies 200.

FIG. 10C shows the resulting structure after a planarization process is performed on the first encapsulant 1020. As shown, the first encapsulant 1020 and first warpage control layer 610 on the first dies 200 are planarized, such that exposed surfaces of the first warpage control layer 610 are substantially level or coplanar with a topmost surface of the first encapsulant 1020. In some embodiments, the planarization process may comprise a CMP process, a grinding process, an etching process, a combination thereof, or the like. In some embodiment, the planarization process may expose TSVs 140 of the first dies 200 such that exposed surfaces of the TSVs 140 are substantially level or coplanar with the topmost surface of the first warpage control layer 610 and the topmost surface of the first encapsulant 1020.

FIG. 10D illustrates the formation of a first bonding layer 1030 on the first carrier substrate 1010. In accordance with some embodiments, a first bonding layer 1030 is formed of a first dielectric material 1040 such as silicon oxide, silicon nitride, or the like. The first dielectric material 1040 may be deposited using any suitable method, such as CVD, high-density plasma chemical vapor deposition (HDPCVD), PVD, atomic layer deposition (ALD), or the like. However, any suitable materials and deposition processes may be utilized. The first bonding layer 1030 may later be used for a dielectric-to-dielectric and metal-to-metal bonding between the first dies 200 and the second dies 1200.

Once the first dielectric material 1040 has been formed, openings in the first dielectric material 1040 are formed to expose the tops of the TSVs 140 in preparation to form first bond pads 1050 within first bonding layer 1030. Once the openings have been formed within the first dielectric material 1040, the openings may be filled with a seed layer (not shown) and a first plate metal to form the first bond pads 1050 within the first bonding layer 1030. The seed layer may be blanket deposited over top surfaces of the first dielectric material and the exposed conductive portions of the TSVs 140 and sidewalls of the openings. The seed layer may comprise a copper layer. The seed layer may be deposited using processes such as sputtering, evaporation, or plasma-enhanced chemical vapor deposition (PECVD), or the like, depending upon the desired materials.

The first plate metal may be deposited over the seed layer (not shown) and first dielectric material 1040 in the first bonding layer 1030 through a plating process such as electroplating or electro-less plating. The first plate metal may comprise copper, a copper alloy, or the like. The first plate metal may be a fill material. A barrier layer (not separately illustrated) may be blanket deposited over top surfaces of the first dielectric material 1040 in the first bonding layer 1030 and sidewalls of the openings before the seed layer. The barrier layer may comprise titanium, titanium nitride, tantalum, tantalum nitride, or the like.

Following the filling of the openings with the first plate metal, a planarization process, such as a chemical mechanical polishing (CMP), is performed to remove excess portions of the seed layer and the first plate metal, forming the first bond pads 1050 within the first bonding layer 1030.

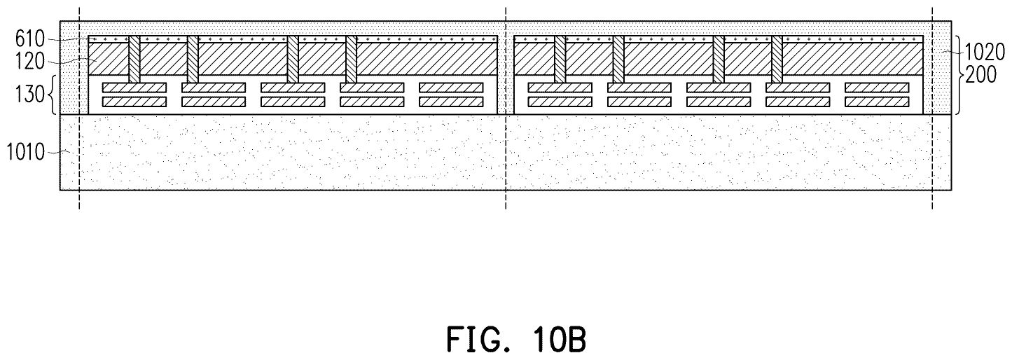

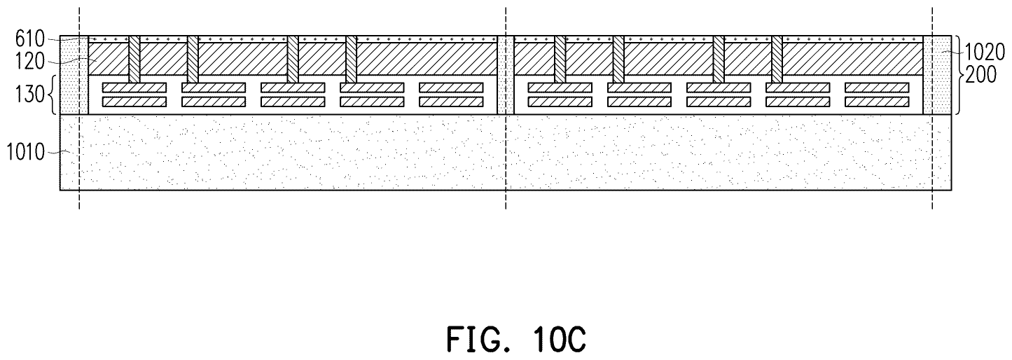

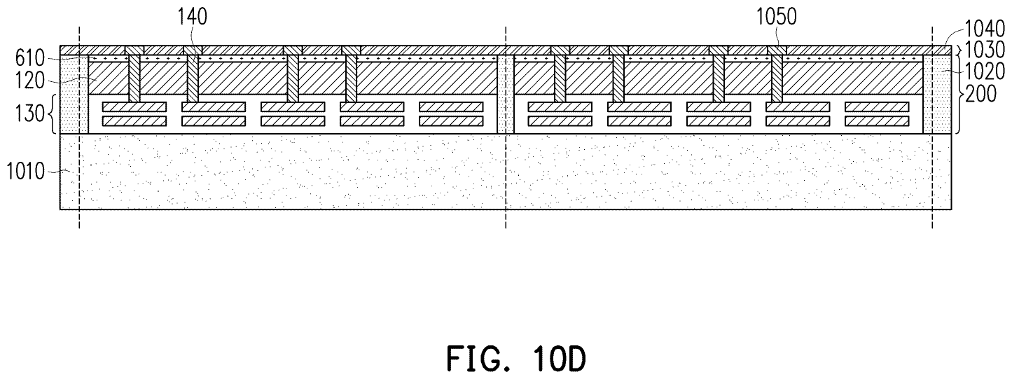

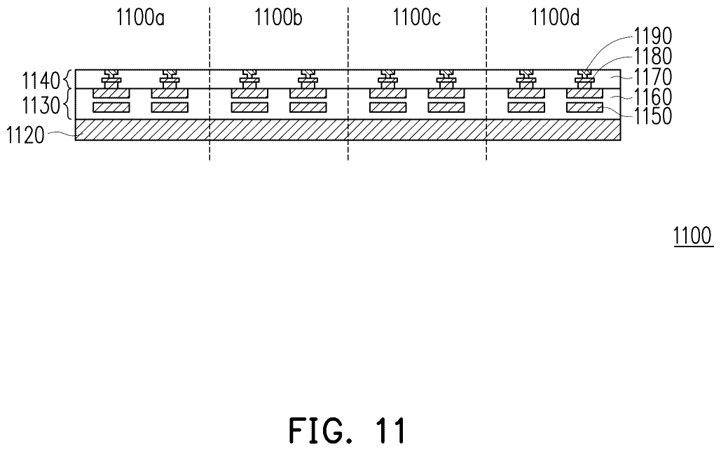

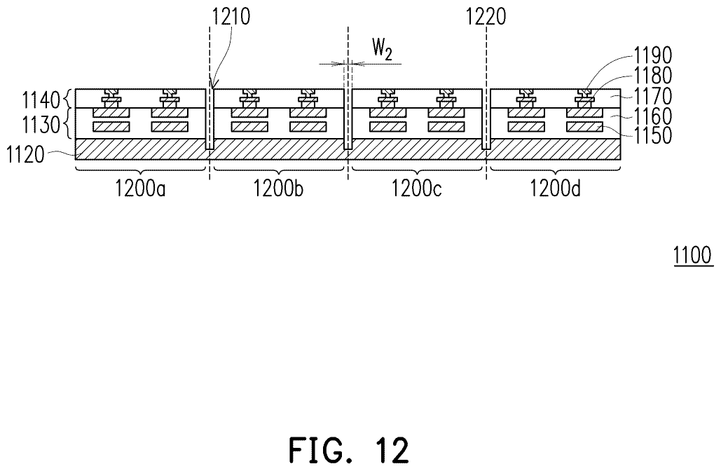

FIG. 11 is a cross-sectional view of the second dies 1200 (FIG. 12) formed on the second wafer 1100 according to some embodiments. The second wafer 1100 may contain a plurality of die regions (1110a, 1110b, 1110c, 1110d, and the like), in which a number of second dies 1200 may be formed in/on the second wafer 1100. Similar to FIG. 1B, the second dies 1200 may be formed as part of a larger wafer or panel form fabrication process having multiple die regions 1110A, 1110B, etc. A number of second dies 1200 (see FIG. 12) may be fabricated as part of a larger wafer or panel form fabrication process having multiple die regions in a two-dimensional array. For the sake of simplicity, only one row of four second dies 1200 formed in second die regions 1110a through 1110d (collectively 1110) are shown. Fewer or more die regions may be utilized on a single wafer arranged in a two-dimensional array in other embodiments.

In the particular embodiment illustrated in FIG. 11, the second dies 1200 fabricated in second die regions 1110a through 1110d comprise a second substrate 1120, a and a second interconnect structure 1130, and an external connection layer 1140.

The second substrate 1120 may be a bulk silicon or other semiconductor material wafer, a silicon-on-insulator (SOI) wafer, or the like. The second substrate 1120 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The second substrate 1120 has an active surface (e.g., the surface facing upward) and an inactive surface (e.g., the surface facing downward). Devices are at the active surface of the second substrate 1120. The devices may be active devices (e.g., transistors, diodes, etc.), capacitors, resistors, etc. The inactive surface may be free from devices. The substrate may also contain one or more TSVs (not shown).

The second interconnect structure 1130 is over the active surface of the second substrate 1120, and is used to electrically connect the devices of the second substrate 1120 to form one or more integrated circuits. The second interconnect structure 1130 may include metallization pattern(s) 1150 in one or more the dielectric layer(s) 1160. Acceptable dielectric materials for the dielectric layers 1160 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, and any suitable means of forming, growing, or depositing the dielectric layers 1160 may be used.

The metallization patterns 1150 may include conductive vias and/or conductive lines to interconnect the devices of the second substrate 1120. The metallization patterns 1150 may be formed of a conductive material, such as a metal, such as copper, cobalt, aluminum, gold, combinations thereof, or the like. The metallization patterns 1150 may be formed by a damascene process, such as a single damascene process, a dual damascene process, or the like. The second interconnect structure 1130 may further include metal pads (e.g., aluminum pads, copper pads, or the like) (not shown), which are connected to a top-most metallization pattern 1150 of the second interconnect structure 1130 through one or more passivation layers. An additional insulating layer (e.g., a passivation layer) may be formed around the metal pads to provide a planar surface on which to form further overlaying features (e.g., bond pads and an insulating bonding layer).

In some embodiments the second interconnect structure 1130 may include optical components such as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. Devices at the active surface of the second substrate 1120 may be used in conjunction with optical components in the second interconnect structure 1130 to complete the optical components.

The external connection layer 1140 is used to facilitate external electrical connections to and from the second dies 1200. The external connection layer 1140 may comprise dielectric layers 1170, metallization layers 1180, and external bonding pads 1190. The dielectric layers 1170 and metallization layers 1180 may be formed using any suitable means, such as those described above in relation to the metallization patterns 1150 and dielectric layers 1160 in the second interconnect structure 1130.

Once the dielectric layers 1170 and metallization layers 1180 of the external connection layer 1140 have been formed, the external bonding pads 1190 may be formed using any suitable means. For example, openings in the dielectric layers 1170 of the external connection layer 1140 may be formed to expose conductive portions of the metallization layers 1180 in preparation to form external bonding pads 1190. Once the openings have been formed within the dielectric layers 1170, the openings may be filled with a seed layer (not shown) and a plate metal (not shown) to form the external bonding pads 1190 within the external connection layer 1140. The seed layer may be blanket deposited over top surfaces of the dielectric layers 1170 and the exposed conductive portions of the metallization layers 1180 in the external connection layer 1140 and sidewalls of the openings. The seed layer may comprise a copper layer. The seed layer may be deposited using processes such as sputtering, evaporation, or plasma-enhanced chemical vapor deposition (PECVD), or the like, depending upon the desired materials.

A plate metal may be deposited over the seed layer (not shown) and dielectric layers 1170 in the external connection layer 1140 through a plating process such as electroplating or electro-less plating. The plate metal may comprise copper, a copper alloy, or the like. The plate metal may be a fill material. A barrier layer (not separately illustrated) may be blanket deposited over top surfaces of the dielectric layers 1170 in the external connection layer 1140 and sidewalls of the openings before the seed layer. The barrier layer may comprise titanium, titanium nitride, tantalum, tantalum nitride, or the like.

Following the filling of the openings with the plate metal, a planarization process, such as a chemical mechanical polishing (CMP), is performed to remove excess portions of the seed layer and the plate metal, forming the external bonding pads 1190 within the external connection layer 1140. In some embodiments bond pad vias may also be utilized to connect the external bonding pads 1190 with underlying conductive portions of metallization layers 1180 in the external connection layer 1140.

FIG. 12 illustrates the start of a multi-step singulation of second dies in accordance with some embodiments. In some embodiments, an etching process is used to partially singulate second die 1200a from second die 1200b, second die 1200b from second die 1200c, and second die 1200c from second die 1200d (collectively second dies 1200). In some embodiments, the trenches 1210 are formed with combination of photolithography and etching processes. For example, the trenches may be formed in a plasma dicing process along the scribe lines 1220. The plasma dicing process may include forming a patterned mask over the external connection layer 1140. The patterned mask may be a photomask that is deposited in a spin-on process over the external connection layer 1140 and patterned by lithography (e.g., exposure and development) to define openings that expose the external connection layer 1140 in the scribe line 1220. The plasma dicing process etches portions of the external connection layer 1140, the second interconnect structure 1130 and the second substrate 1120 through the patterns (e.g., openings) in the patterned mask. The trenches 1210 may extend through the external connection layer 1140 and second interconnect structure 1130 to a desired depth into the second substrate 1120. However, the trenches 1210 may not extend fully through the second substrate 1120, and lower portions of the second substrate 1120 may remain to connect the second dies 1200 together in the second wafer 1100. In some embodiments, the depth of the trenches 1210 may be between 1 micrometer (μm) and 750 μm into the second substrate 1120.

In some embodiments the etching process may be performed in multiple steps and may utilize a plasma dry etch process and/or a reactive ion etch (RIE). For example, a first reactive ion etch using reactive gases such as CF₄, C₄F₈, CHF₃, or CH₃F may be performed to preferentially etch through the dielectric layers 1170 of the external connection layer 1140 and the dielectric layers 1160 of the second interconnect structure 1130. A second reactive ion etch may then be performed using gases such as SF₆ or NF₃ to preferentially etch the second substrate 1120. The depth of the etch may be controlled by varying the timing of the etching process, among other process parameters. In some embodiments a third etch may be performed where the third etch is a wet etch to cure any surface defects in the second dies 1200 resulting from a dry etching process. In some embodiments, the RIE uses an argon-based plasma, an oxygen-based plasma, a nitrogen-based plasma, or the like. However, any suitable method of etching trenches to singulate the second dies 1200 may be utilized. In some cases, the width (W₂) of the trench formed by etching between the each of the second dies 1200 may be between 0.1 μm and 1000 μm. In some embodiments the width (W₁) of the trench may be narrow enough to preclude later deposition in the trench. In some embodiments, the width (W₁) of the trench may be 8 μm or less to limit deposition in the trench.

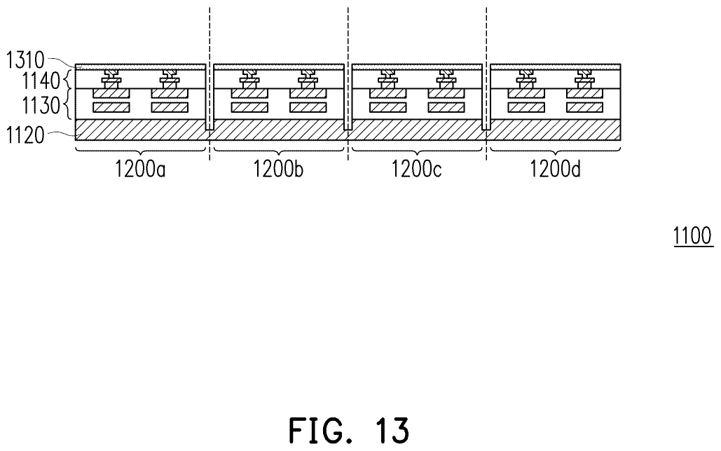

FIG. 13 illustrates the formation of a protective layer 1310 over the external connection layer 1140 of the second dies 1200 according to some embodiments. In some embodiments, a surface treatment may be performed in the trenches 1210 prior to forming the protective layer 1310. In some embodiments, the surface treatment is a fluorine-based treatment, such as a wet cleaning process using a fluorine-comprising solution, a fluorine-based plasma process, or the like. In some embodiments, the fluorine-based plasma process may be performed at a temperature in a range of 25° C. to 500° C. and at a pressure of 0 Torr to 1.316×10−3 Torr (one atmosphere). Other treatments that form hydrophobic surfaces may be applied in other embodiments. The surface treatment makes the surfaces of the trenches 1210 hydrophobic so that a subsequently formed protective layer 1310 can be deposited over the external connection layer 1140 without being significantly deposited in the trenches 1210. When the surface treatment is a fluorine-based treatment, the resulting surface regions may likewise comprise fluorine and be referred to as a fluorinated protection layer. For example, surface regions may comprise 5 weight % (wt%) or more fluorine, which advantageously results in hydrophobic surfaces in the trenches 1210. The surface regions may further comprise carbon, oxygen, silicon, nitrogen, or a combination thereof. The specific material composition of the surface regions may depend on a material of the external connection layer 1140, the second interconnect structure 1130 and/or the second substrate 1120 on which the surface regions are formed. For example, portions of the surface regions on the second substrate 1120 may comprise fluorine and silicon while portions of the surface regions on the external connection layer 1140 and/or second interconnect structure 1130 may comprise fluorine in combination with carbon, oxygen, nitrogen and/or silicon.

The surface treatment may be performed while a patterned mask covers the external connection layer 1140. As a result, the surface regions can be selectively formed in the trenches 1210 without blanket forming the surface regions over the external connection layer 1140. For example, after the surface treatment, top surface of the external connection layer 1140 may remain hydrophilic so that protective layer 1310 can be deposited thereon. After the surface treatment, the patterned mask may be removed. For example, when the patterned mask is a photomask, the patterned mask may be stripped away with an ashing process.

A protective layer 1310 may then be deposited over the external connection layer 1140. In some embodiments, the protective layer 1310 is a back side anti-reflective coating (BARC) layer that is deposited by a spin-on process, or the like. As a result of the surface treatment and the hydrophobic surface regions, the protective layer 1310 may not be significantly deposited within the trenches 1210. Keeping the protective layer 1310 from being deposited in the trenches 1210 achieves advantages such as reduced manufacturing defects and improved yield. In other embodiments, the protective layer 1310 may be a photoresist, or other suitable material, deposited or formed using suitable application processes.

In some embodiments, the protective layer 1310 may be between 1 nm and 100 nm μm thick. A planarization process (e.g., a chemical mechanical polish (CMP) or the like) may be performed such that top surfaces of the protective layer 1310 is coplanar (within process variations). In some embodiments, a spin on process may be used to control uniformity of the protective layer 1310.

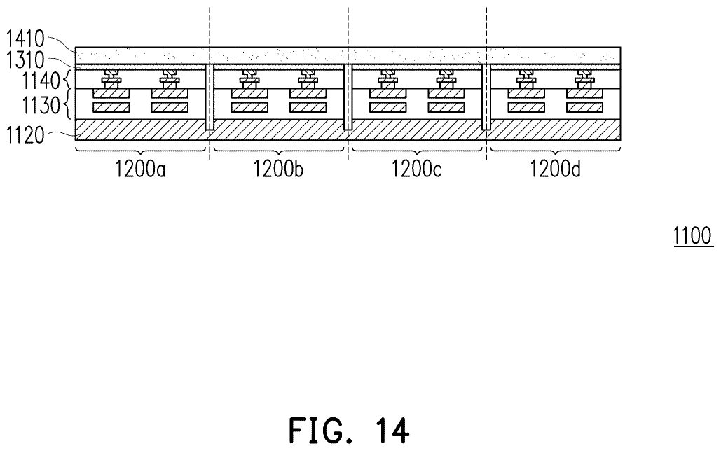

FIG. 14 illustrates the application of a back-side grinding (BG) tape according to some embodiments. As shown, BG tape 1410 is adhered to the second wafer 1100, such as to a top surface of the protective layer 1310. The BG tape 1410 supports the second wafer 1100 during the second dies 1200 final singulation and following preparation process. The protective layer 1310 acts as an intermediary, buffer between the second wafer 1100 and the BG tape 1410. For example, the protective layer 310 protects a top surface of the external connection layer 1140 from direct contact with the BG tape 410, reducing the risk of damage to the external connection layer 1140.

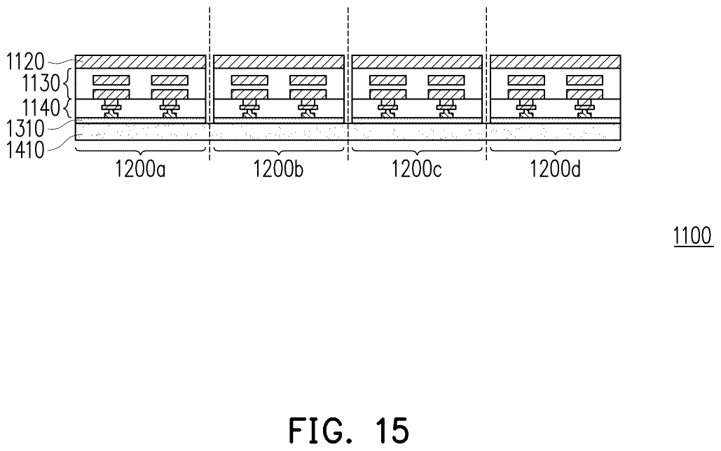

FIG. 15 illustrates the thinning of the second substrates 1120 of the second dies 1200 according to some embodiments. As shown, the second wafer 1100 may be flipped over such that the BG tape 410 is generally oriented on the bottom side of the second wafer 1100. The second substrate 1120 may then be thinned thereby completing the singulation of each of the second dies 1200. In embodiments where the second substrate 1120 includes TSVs, the second substrate 1120 may be thinned until the TSVs have been exposed. In an embodiment, the second substrate 1120 may be thinned using, e.g., a CMP process, a grinding process, slicing, or the like. Further, once exposed, the TSVs may be further exposed using, e.g., one or more etching processes, such as a wet etch process in order to recess the second substrate 1120 so that the TSVs extend out of the second substrate 1120.

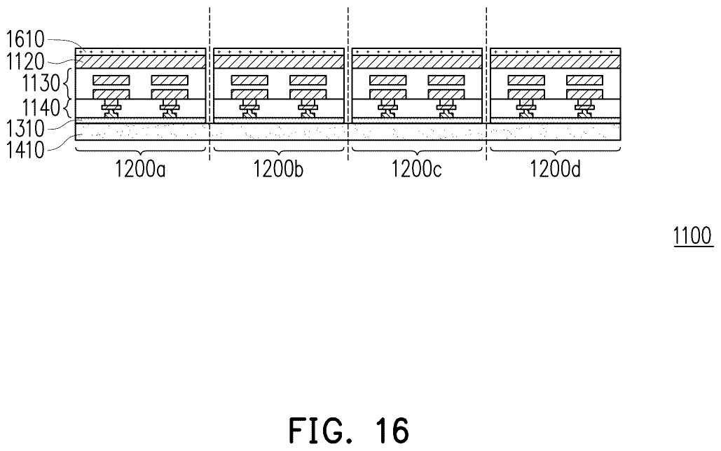

FIG. 16 illustrates a second warpage control layer 1610 to the thinned second substrate 1120 on the front side of the second dies 1200 according to some embodiments. In some embodiments the second warpage control layer 1610 may be silicon oxide, silicon nitride, silicon oxynidtride, silicon carbide, organic material, or some other dielectric material. The second warpage control layer 1610 may be deposited on the second substrate 1120, for example, by spin coating, lamination, chemical vapor deposition (CVD), atomic layer deposition (ALD), physical vapor deposition (PVD), high-density plasma chemical vapor deposition (HDPCVD), thermal oxidation, a combination thereof, and/or the like. A planarization process (e.g., a chemical mechanical polish (CMP) or the like) may be performed such that top surfaces of the second warpage control layer 1610 is coplanar (within process variations). In embodiments where the second substrate 1120 has been recessed to expose portions of any included TSVs, the planarization process may be performed such that the top surfaces of the second warpage control layer 1610 and the TSVs (not shown) are coplanar (within process variations). In some embodiments, second warpage control layer 1610 is the same material deposited in the same processes described above with regard to the first warpage control layer 610, but this is not a limitation and different materials and processes could be used for the respective warpage control layers.

In some embodiments, due to the small width of trenches 1210 between second dies 1200 (approximately 8 μm), as well as due to the selected process conditions, process gases can be substantially precluded from interacting with the etched sidewalls of the second dies 1200. In embodiments where the surface treatment is performed in the trenches 1210 of the second dies 1200 prior to forming the protective layer 1310, the surface treatment may further prevent formation of the second warpage control layer 1610 on the etched sidewalls of the second dies 1200. In other embodiments, similar to those described with respect to the first warpage control layer 610, portions of the second warpage control layer 1610 may coat the sidewalls of the second dies 1200, but this is not a limitation and different materials and processes could be used for the respective second warpage control layer 1610.

In some embodiments the second warpage control layer 1610 is between 10 Å and 1000 Å thick. In some embodiments, the second warpage control layer 1610 may include multiple layers of silicon oxide, silicon nitride, silicon oxynidtride, silicon carbide, organic material, or some other dielectric material deposited or formed using suitable processing techniques. Once formed, the second warpage control layer 1610 adds rigidity to the second dies 1200 and limits the amount of curvature that second dies 1200 will experience during later pick-and-place operations (for example, as described below). By limiting the curvature introduced in the second die, the die may already be, or have time to straighten within the timing parameters for bonding. For example, a specific moisture content or wetness of the die may be a limiting factor in production, where the die dries over time. By reducing the amount of curvature introduced, the die is more likely to straighten to within tolerances (if outside of those after the pick-and-place) and non-bonding or bonding bulges can be reduced. Accordingly, higher manufacturing yields, lowered production costs, lowered material waste, and increased manufacturing efficiencies are realized.

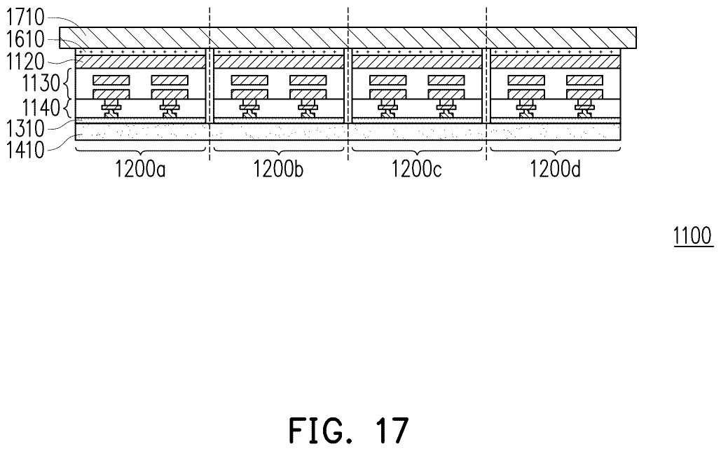

FIG. 17 illustrates application of a dicing tape 1710 to the second dies 1200 according to some embodiments. The dicing tape 710 supports the second dies 1200 retains the integrity of the second wafer 1100 during the completion of the second dies 1200 preparation process. In some embodiments, the dicing tape may be in contact with top metal portions of TSVs in the second substrate 1120 where included, as well as the second warpage control layer 1610.

FIG. 18 illustrates removal of the BG tape 1410 and reorientation of the second wafer 1100 according to some embodiments. As shown, the second wafer 1100 is again flipped and the BG tape 1410 removed to expose the protective layer 1310. The protective layer 1310 may also be removed at this point, as shown in FIG. 18, or after the pick-and-place operation described below, but prior to bonding the second dies 1200 to the first dies 200. In some embodiments, a further planarization process, such as CMP, may be performed on external connection layer 1140 to remove residue and cure imperfections (within process parameters) caused by removal of the BG tape 1410.

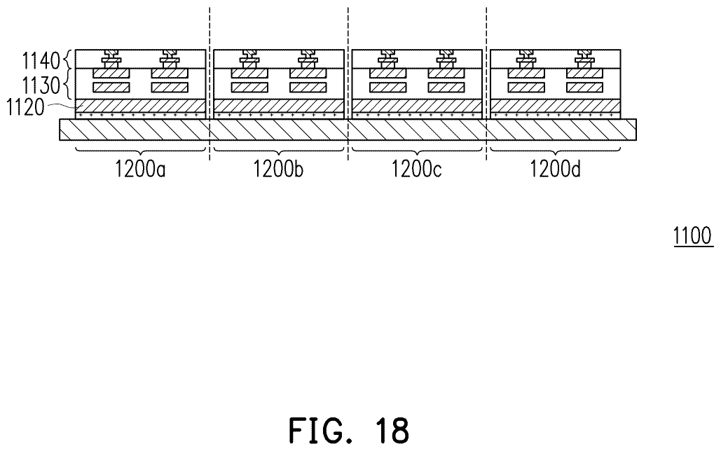

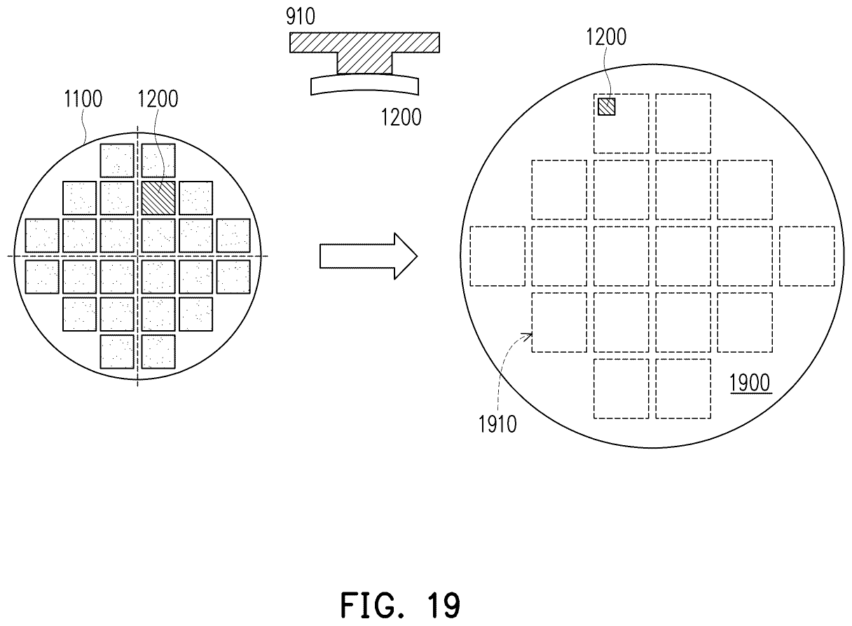

FIG. 19 illustrates placement of known good second dies 1200 from the second wafer 1100 on to a second reconstruction wafer 1900 or film according to some embodiments. Prior to the singulation of the second wafer 1100 using the etching process described above, the second wafer 1100 may have been tested to identify each known good die in the second dies 1200. After the singulation process a pick-and-place device may be used to move each known good second die 1200 to the second reconstruction wafer 1900. In some embodiments, the reconstruction wafer may comprise a release film. Because the second dies 1200 are not flipped during the pick-and-place process, the second warpage control layer 1610 of each second die 1200 will be closest to the second reconstruction wafer 1900.

It is during this movement, from the second wafer 1100 supported by the dicing tape 1710, to the second reconstruction wafer 1900, each second die 1200b will be held by the pick-and-place machine 910, but unsupported on the bottom of the second die 1200. Accordingly, the natural tendency of second die 1200 is to warp downward introducing curvature into the second die 1200. As addressed above, warpage control layer 1610 will significantly reduce or eliminate such warpage.

In accordance with some embodiments, the known good second dies 1200 may be placed on the second reconstruction wafer 1900 in positions corresponding to a bonding position in a footprint 1910 of the first dies 200 on the first reconstruction wafer 900. For the sake of simplicity, only one footprint 1910 on the second reconstruction wafer 1900 has been labeled, and only one known good second die 1200 on the second wafer 1100 is shown transferred to the second reconstruction wafer 1900. However, no limitation is intended on the number of known good second dies 1200 singulated from the second wafer 1100. Similarly, no limitations are intended on the number of known good second dies 1200 that may be transferred from the second wafer 1100 to the second reconstruction wafer 1900. Design requirements, space constraints of the second wafer 1100 and second reconstruction wafer 1900 will factor in, however.

FIG. 20 illustrates a potential resulting structure having two second dies 1200 stacked on each first die 200 on the first carrier substrate 1010 after a second switch process, according to some embodiments.

In some embodiments, a wafer-to-wafer stacking may be utilized to position the known good second dies 1200 on the known good first dies 200 and the first carrier substrate 1010 during a second switch process. The second reconstruction wafer 1900 may then be de-bonded from the second known good dies 1200 revealing the second warpage control layer 1610 on each known good second die 1200. In embodiments where the second dies 1200 include TSVs in the second substrate 1120, the metallic portions of the TSVs will also be revealed.

In some embodiments, a further pick-and-place operation may be performed to transfer the known good second dies 1200 into position on top of the first dies 200 and first carrier substrate 1010. During the switch process from the second reconstruction wafer 1900, the associated known good second dies 1200, are placed on associated first dies 200 such that the external connection layer 1140 of the second dies 1200 is in direct contact with the first bonding layer 1030 on an associated first die 200. The second warpage control layer 1610 on each second die 1200 is furthest from the first carrier substrate 1010.

In a particular embodiment which utilizes a dielectric-to-dielectric and metal-to-metal bonding process between the first dies 200 and the second dies 1200, the process may be initiated by activating the surfaces of the second dies 1200 and the surfaces of the first bonding layer 1030. Activating the top surfaces of the first bonding layer 1030 and the top surface of the second dies 1200 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the second dies 1200 to the first dies 200.

After the activation process the first dies 200 and second dies 1200 may be cleaned using, e.g., a chemical rinse, and then the second dies 1200 are aligned and placed into physical contact with the first dies 200 such that the front side of each second dies 1200 (e.g. the exposed surface of the external connection layer 1140) is closest to the back side of each first die 200 (e.g., the first substrate 120).

The first dies 200 and second dies 1200 are then subjected to thermal treatment and contact pressure to bond the second dies 1200 to the first dies 200. For example, the first dies 200 and the second dies 1200 may be subjected to a pressure of about 200 kPa or less, and a temperature between about 25° C. and about 250° C. to fuse the second dies 1200 with the first dies 200. The first dies 200 and the second dies 1200 may then be subjected to a temperature at or above the eutectic point for material of the first bond pads 1050 and bonding pads in the external connection layer 1140, e.g., between about 150° C. and about 650° C., to fuse the metal. In this manner, the second dies 1200 form a dielectric-to-dielectric and metal-to-metal bonded device with the first dies 200. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

In some embodiments, where the second dies 1200 are smaller than the first dies 200, for example as shown in FIG. 20, a dummy chip 2010 may further be included over the first dies 200 to occupy space and provide support and rigidity to the overall package. Another pick-and-place operation may be used according to some embodiments to place dummy chips 2010 on the first carrier substrate 1010 and first dies 200. Dummy chips 2010 may be included in the dielectric-to-dielectric bond with the first dies 200 if they are placed on the first dies prior to bonding the second dies 1200. Dummy chips 2010 may also be secured to the first carrier substrate 1010 through the encapsulation process described below, or a combination of methods may be used.

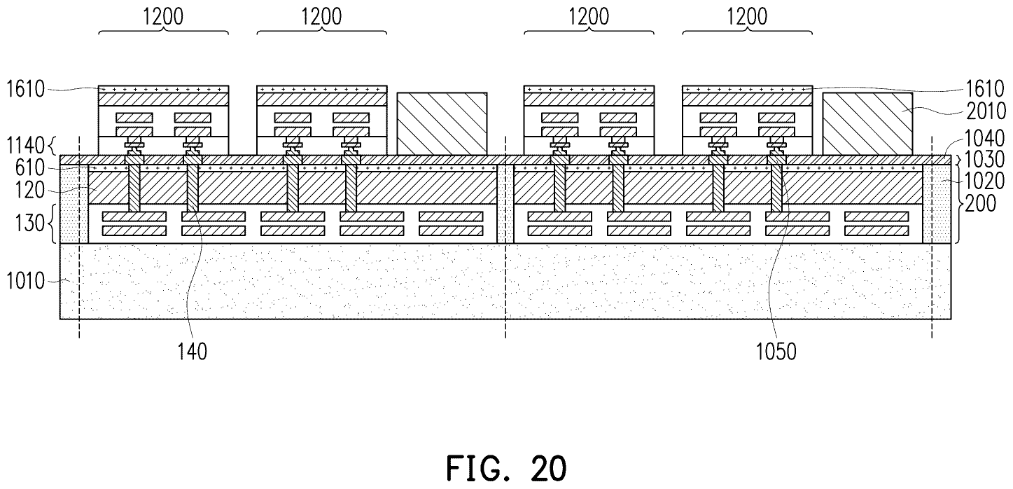

FIG. 21 shows the application of an encapsulant 2110 according to some embodiments. As shown, an encapsulant 2110 is formed over the first carrier substrate 1010, and over and surrounding the first dies 200, the second dies 1200, and the dummy chip 2010. In some embodiments, the encapsulant 2110 may comprise one or more layers of non-photo-patternable insulating materials such as silicon nitride, silicon oxide, phosphosilicate glass (PSG), borosilicate glass (BSG), boron-doped phosphosilicate glass (BPSG), a combination thereof, or the like, and may be formed using CVD, PVD, ALD, a spin-on coating process, a combination thereof, or the like. In other embodiments, the encapsulant 2110 may comprise one or more layers of photo-patternable insulating materials such as polybenzoxazole (PBO), polyimide (PI), benzocyclobutene (BCB), a combination thereof, or the like, and may be formed using a spin-on coating process, or the like. Such photo-patternable insulating materials may be patterned using similar photolithography methods as a photoresist material. In other embodiments, the encapsulant 2110 may comprise a molding compound, such as an epoxy, a resin, a moldable polymer, a combination thereof, or the like. The molding compound may be applied while substantially liquid, and then may be cured through a chemical reaction, such as in an epoxy or resin. In other embodiments, the molding compound may be an ultraviolet (UV) or thermally cured polymer applied as a gel or malleable solid capable of being disposed around and between the first dies 200, the second dies 1200, and the dummy chip 2010.

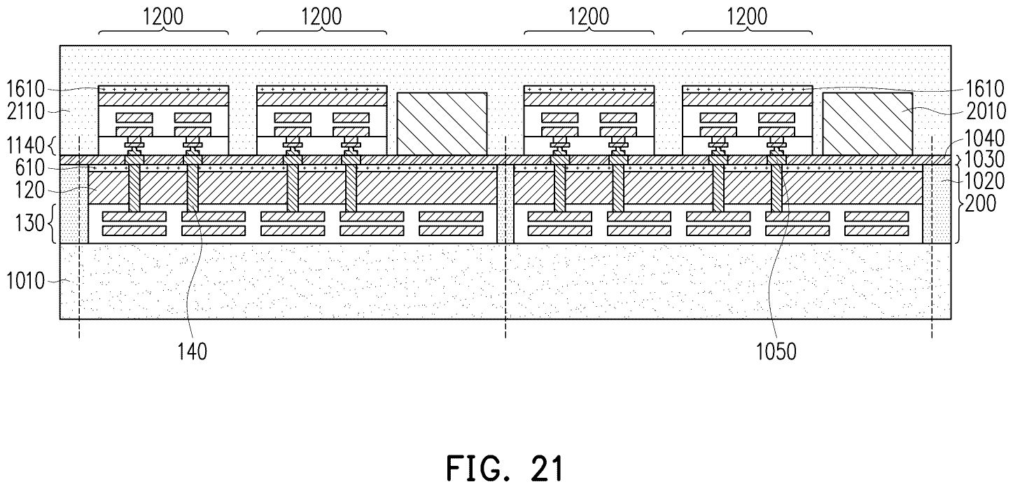

FIG. 22 shows the resulting structure after a planarization process is performed on the encapsulant 2110. As shown, the encapsulant 2110 and second warpage control layer 1610 on the second dies 1200 are planarized, such that exposed surfaces of the second warpage control layer 1610 are substantially level or coplanar with a topmost surface of the encapsulant 2110. In some embodiments, the planarization process may comprise a CMP process, a grinding process, an etching process, a combination thereof, or the like. In some embodiment, the planarization process may expose TSVs of the second dies 1200, where such TSVs are included, such that exposed surfaces of the TSVs are substantially level or coplanar with the topmost surface of the second warpage control layer 1610 and the topmost surface of the encapsulant 2110. In some embodiments, the dummy chip 2010 topmost surface will be covered by the encapsulant 2110 after the planarization process. In some embodiments where multiple dummy chips 2010 are included in a single package, some or all dummy chips 2010 may remain covered by the encapsulant 2110 after the planarization, and some or all dummy chips 2010 topmost surface may be exposed and coplanar with the topmost surface of the encapsulant 2110 (within process parameters).

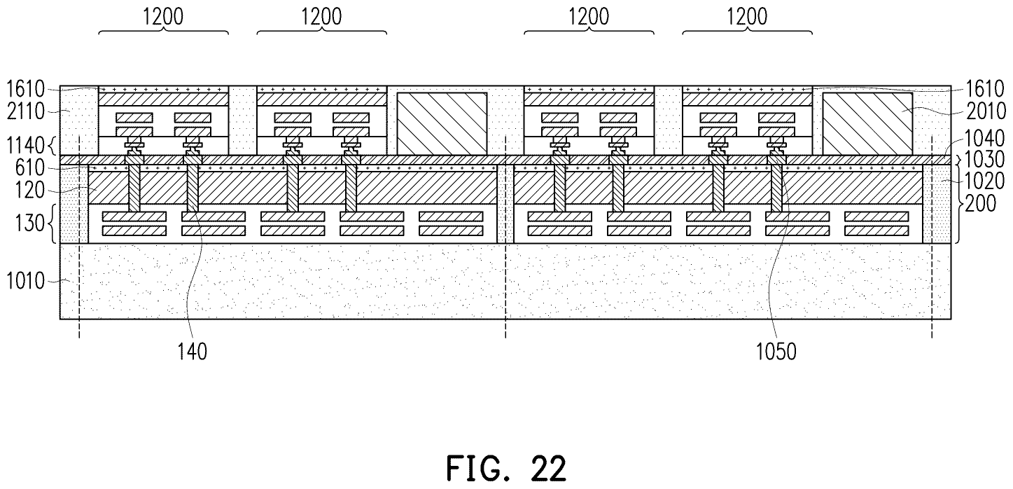

FIG. 23 illustrates a bonding layer formation, in accordance with some embodiments. A first bonding layer 2310 may be formed of a dielectric material such as silicon oxide, silicon nitride, or the like. The dielectric material may be deposited using any suitable method, such as CVD, high-density plasma chemical vapor deposition (HDPCVD), PVD, ALD, or the like.

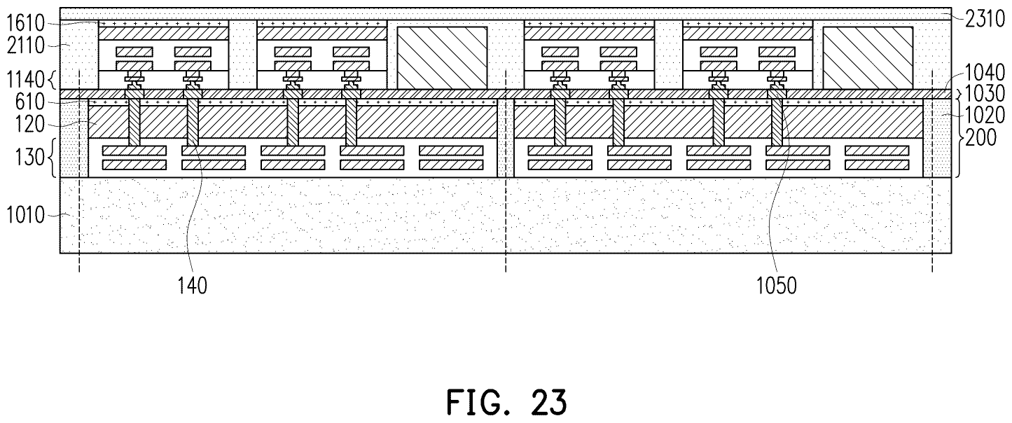

FIG. 24 illustrates the bonding of a second carrier substrate 2410 over the intermediate package shown in FIG. 23, in accordance with some embodiments. A second carrier substrate 2410 is provided having a second bonding layer 2420 of dielectric material such as silicon oxide, silicon nitride, or the like. The dielectric material may be deposited using any suitable method, such as CVD, HDPCVD, PVD, ALD, thermal oxidation, or the like. The second carrier substrate is placed over the top of the intermediate package shown in FIG. 23 such that such that the first bonding layer 2310 is in contact with the second bonding layer 2420.

The second carrier substrate 2410 may be a bulk silicon or other semiconductor material wafer, a silicon-on-insulator (SOI) wafer, or the like. The second carrier substrate 2410 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The second carrier substrate 2410 may also contain one or more TSVs (not shown).

The bonding process may be initiated by activating the exposed surfaces of the first bonding layer 2310 and/or the second bonding layer 2420. Activating the exposed surfaces of the bonding layers may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the second carrier substrate 2410 to the package in its intermediate state, as illustrated in FIG. 24 over first carrier substrate 1010.

After the activation process, the first carrier substrate 1010, associated dies, and the second carrier substrate 2410 may be cleaned using, e.g., a chemical rinse. The second carrier substrate 2410 is then aligned and placed into physical contact over the first carrier substrate 1010 such that the first bonding layer 2310 is in direct physical contact with the second bonding layer 2420. In some embodiments, the first carrier substrate 1010 and the second carrier substrate 2410 are equal in width. In the terms of this disclosure, equal to is within a 10 percent variation.

The intermediate package shown in FIG. 23 and the second carrier substrate 2410 are then subjected to thermal treatment and contact pressure to bond the second carrier substrate 2410 to the intermediate package shown in FIG. 23. For example, first carrier substrate 1010 and the second carrier substrate 2410 may be subjected to a pressure of about 200 kPa or less, and a temperature between about 25° C. and about 250° C. to fuse the second carrier substrate 2410 with the first carrier die stack on substrate 1010. In some embodiments, the bonded carriers are subsequently baked, annealed, pressed, or otherwise treated to strengthen or finalize the bond.

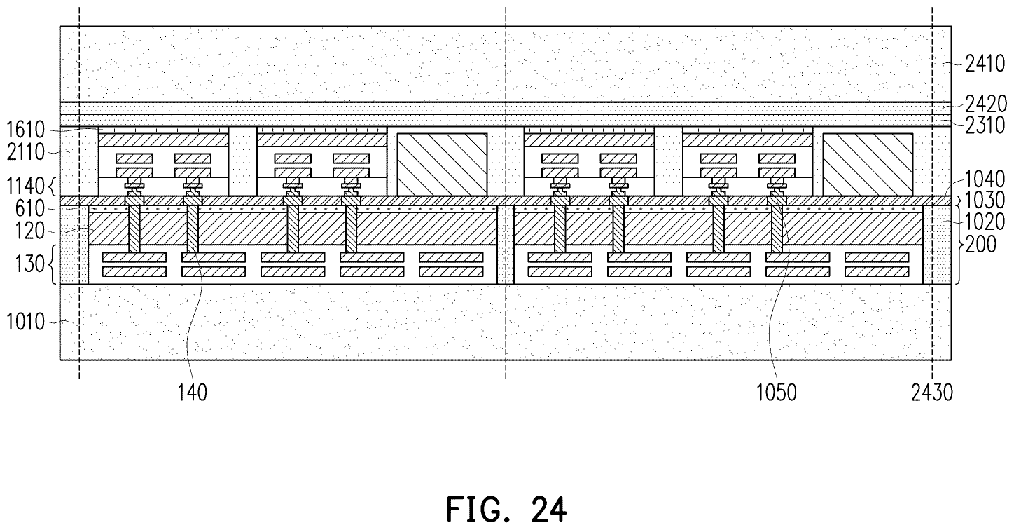

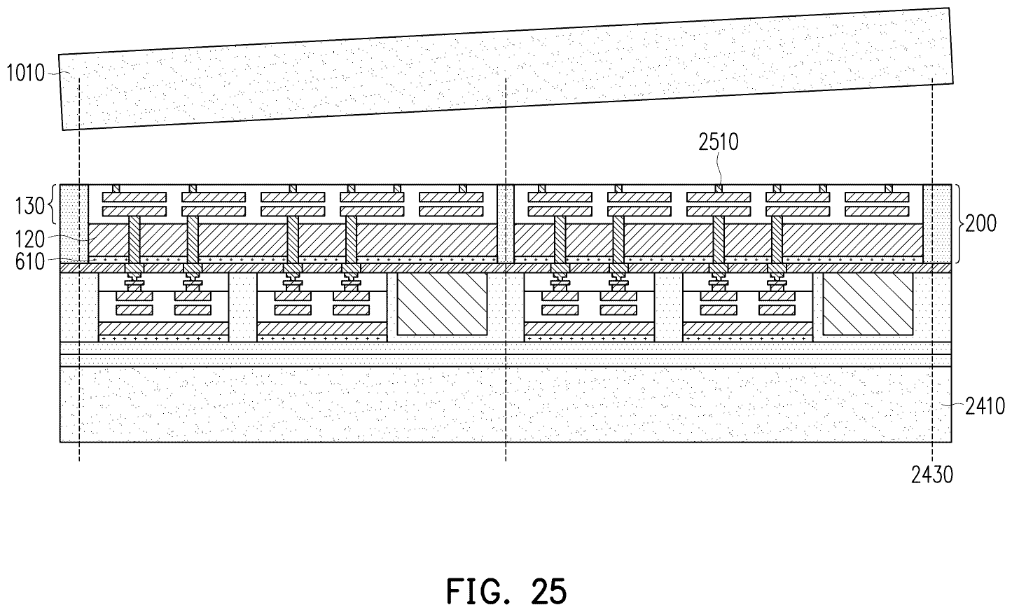

FIG. 25 illustrates removal of the first carrier, in accordance with some embodiments. The stack comprising the first carrier substrate 1010, first dies 200, second dies 1200, dummy chip(s) 2010, and the second carrier substrate 2410 may first be flipped over to orient the first carrier substrate 1010 side for processing. The first carrier substrate may then be removed from the stack to leave the first dies 200, second dies 1200, dummy chip(s) 2010, and the second carrier substrate 2410. The first carrier substrate 1010 may be removed by a thinning process, debonding process, or the like, such that top surfaces of the first interconnect structure 130 of the first dies 200 are exposed. The thinning process may be performed, e.g., using a mechanical grinding, chemical approaches, or chemical mechanical polishing (CMP) process whereby chemical etchants and abrasives are utilized to react with and grind away the first carrier substrate 1010.

In the embodiment shown in FIG. 25, topmost metallization patterns 2510 may also be formed to provide electrical connection to metallization patterns 150 in the first interconnect structure 130 of the first dies 200. The topmost metallization patterns 2510 may be formed of a conductive material, such as a metal, such as copper, cobalt, aluminum, gold, combinations thereof, or the like. The topmost metallization patterns 2510 may be formed by a damascene process, such as a single damascene process, a dual damascene process, or the like. However, any suitable method of forming topmost metallization patterns 2510 may be used. In some embodiments, the topmost metallization patterns 2510 may be formed in earlier portions of the process, including during the formation of first dies 200. In such cases, removal of the first carrier substrate 1010 may further include removal of portions of the first interconnect structure 130 of the first dies 200 to expose the topmost metallization patterns 2510 in the first interconnect structure 130. As such, the front side of the first dies 200 may have a planar surface, within process parameters.

Furthermore, while the CMP process described above is presented as one illustrative embodiment, it is not intended to be limiting to the embodiments. Any other suitable removal process may be used to thin or remove the first carrier substrate 1010 and/or a portion of the first interconnect structure 130 of the first dies 200. For example, a series of chemical etches may be utilized. This process and any other suitable process may be utilized to planarize, within process parameters, the first carrier substrate 1010 and first interconnect structure 130 of the first dies 200, and all such processes are fully intended to be included within the scope of the embodiments.

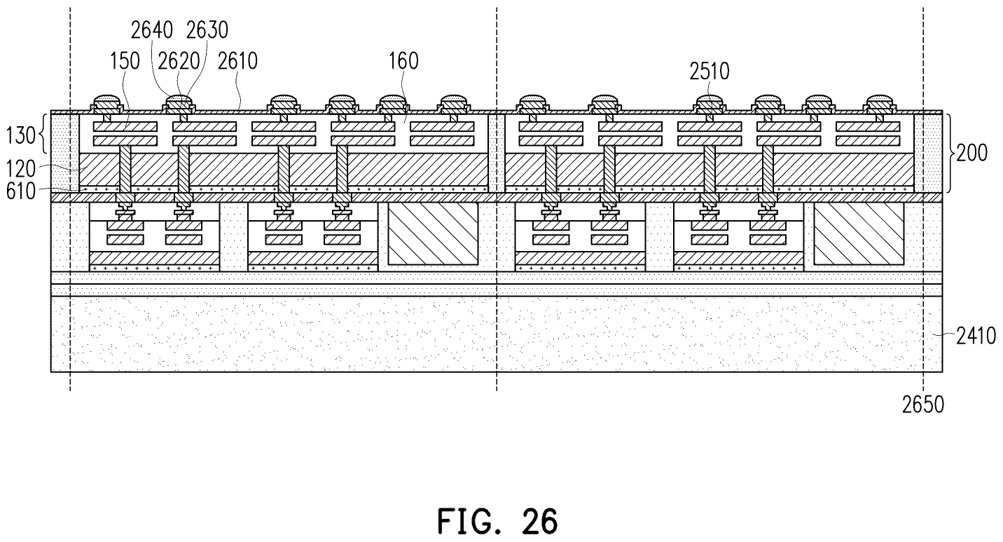

FIG. 26 illustrates the formation of a passivation layer 2610 and external connections, according to some embodiments. In an embodiment, metallization contact pads 2620 are formed over a top most dielectric layer 160 of the first interconnect structure 130 of the first dies 200. The metallization contact pads 2620 may be formed of a conductive material, such as a metal, such as copper, cobalt, aluminum, gold, combinations thereof, or the like. The metallization contact pads 2620 may be formed by a damascene process, such as a single damascene process, a dual damascene process, or the like. However, any suitable method may be used to form the metallization contact pads 2620.

In an embodiment, a passivation layer 2610 may be formed over the top most dielectric layer 160 of the first interconnect structure 130 of the first dies 200 and over the first metallization contact pads 2620. The passivation layer 2610 may be a material such as a nitride, an oxide, a polyimide, a low-temp polyimide, a solder resist, combinations thereof, or the like. Once formed, the passivation layer 2610 may be patterned (e.g., using a suitable photolithographic and etching process) to expose portions of the metallization contact pads 2620.

In an embodiment, under bump metallizations (UBMs) 2630 are formed for external connection to the first dies 200. The UBMs 2630 have bump portions on and extending along the major surface of the passivation layer 2610, and have via portions extending through the passivation layer 2610 to physically and electrically couple the metallization contact pads 2620. The UBMs 2630 may be formed of the same material, and in a similar manner, as the metallization contact pad 2620.

In an embodiment, conductive connectors 2640 are formed on the UBMs 2630. The conductive connectors 2640 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 2640 may include a conductive material such as solder, copper, aluminum, gold, nickel, silver, palladium, tin, the like, or a combination thereof. In some embodiments, the conductive connectors 2640 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 2640 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

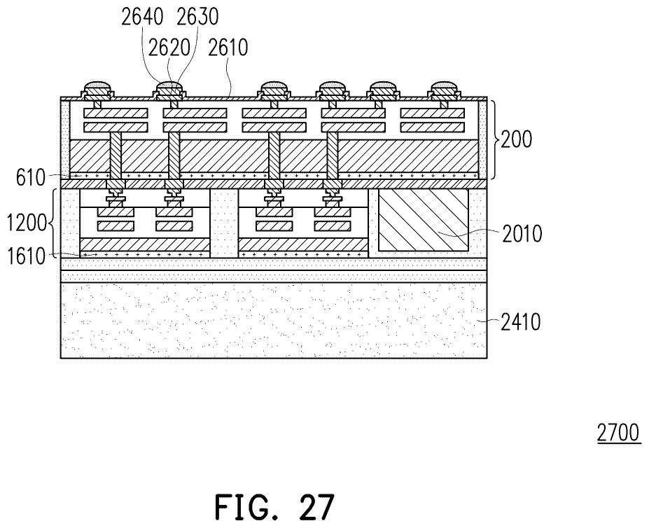

Subsequently, in some embodiments, a singulation process may be performed around peripheries of the illustrated package region along scribe lines 2650. The singulation process may include, for example, sawing, laser ablation, etching, a combination thereof, or the like. However, the singulation process may not be performed in certain regions intermediate regions. A singulated system on integrated chip (SoIC) package 2700, in accordance with some embodiments, is shown in FIG. 27. In some embodiments the second carrier substrate 2410 may be thinned or removed similar to the removal or thinning of the first carrier substrate 1010.

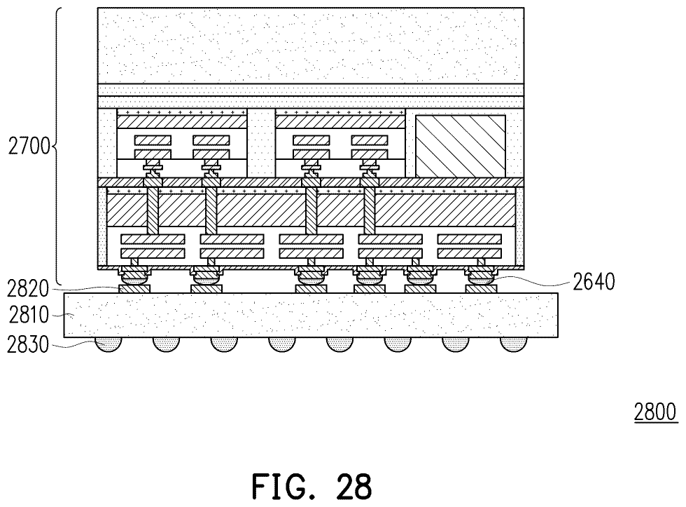

FIG. 28 illustrates that once the singulated SoIC package 2700 has been formed, the singulated SoIC package 2700 may be attached to a substrate 2810 that is used to couple the singulated SoIC package 2700 with other devices to form, for example, a flip chip device 2800, in accordance with some embodiments. The singulated SoIC package 2700, and another other dies or packages, may be bonded to a substrate 2810 with, e.g., conductive connectors 2640. In an embodiment the substrate 2810 may be a package substrate, which may be a system board such as a printed circuit board (PCB) or the like. The substrate 2810 may include one or more dielectric layers and electrically conductive features, such as conductive lines and vias. In some embodiments, the second substrate 2810 may include through-vias, active devices, passive devices, and the like. The second substrate 2810 may further include conductive pads 2820 formed at the upper (shown) and lower (not shown) surfaces of the second substrate 2910.

External connectors 2830 may be formed on a side of the substrate 2810 opposite the singulated SoIC package 2700. External connectors 2830 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The external connectors 2830 may include a conductive material such as solder, copper, aluminum, gold, nickel, silver, palladium, tin, the like, or a combination thereof. In some embodiments, the external connectors 2830 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the external connectors 2830 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The external connectors 2830 may be aligned with corresponding conductive connections on the second side of the substrate 2810, opposite the singulated SoIC package 2700. The external connectors 2830 may then be subsequently reflowed in order to bond the flip chip device 2800 to further devices. However, any suitable bonding process may be used to subsequently connect to the flip chip device 2800.

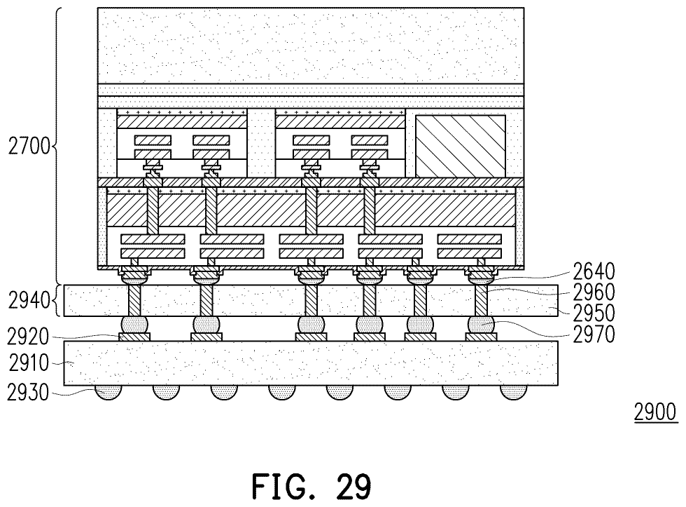

FIG. 29 illustrates that once the singulated SoIC package 2700 has been formed, the singulated SoIC package 2700 may be attached to a substrate 2910 that is used to couple the singulated SoIC package 2700 with other devices to form, for example, a chip-on-wafer-on-substrate (CoWoSR) device 2900. The singulated SoIC package 2700, and any other dies or packages, may be bonded to a first side of an interposer 2940 using, e.g., the conductive connectors 2640. In an embodiment, the interposer 2940 comprises a semiconductor substrate 2950, through device vias (TDVs) 2960, and first external connectors 2970. The semiconductor substrate 2950 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

Optionally, active devices (not separately illustrated) may be added to the semiconductor substrate 2950. The active devices may comprise a wide variety of active devices and passive devices such as capacitors, resistors, inductors and the like that may be used to generate the desired structural and functional requirements of the design for the semiconductor substrate 2950. The active devices may be formed using any suitable methods either within or else on the semiconductor substrate 2950.

The metallization layers (not shown) may be formed over the semiconductor substrate 2950 and the active devices and are designed to connect the various devices to form functional circuitry. In an embodiment the metallization layers may be formed of alternating layers of dielectric (e.g., low-k dielectric materials, extremely low-k dielectric material, ultra low-k dielectric materials, combinations of these, or the like) and conductive material and may be formed through any suitable process (such as deposition, damascene, dual damascene, etc.). However, any suitable materials and processes may be utilized.

Additionally, at any desired point in the manufacturing process, the TDVs 2960 may be formed within the semiconductor substrate 2950 and, if desired, one or more layers of the metallization layers (not shown), in order to provide electrical connectivity from a front side of the semiconductor substrate 2950 to a back side of the semiconductor substrate 2950. In an embodiment the third TDVs 2960 may be formed by initially forming through device via (TDV) openings into the semiconductor substrate 2950 and, if desired, any overlying metallization layers (e.g., after a desired third metallization layer has been formed but prior to formation of a next overlying third metallization layer). The TDV openings may be formed by any suitable method.

Once the singulated SoIC package 2700, and any other dies or packages, have been bonded to the interposer 2940, the interposer 2940 may be bonded to a second substrate 2910 with, e.g., the first external connectors 2970. In an embodiment the second substrate 2910 may be a package substrate, which may be a system board such as a printed circuit board (PCB) or the like. The second substrate 2910 may include one or more dielectric layers and electrically conductive features, such as conductive lines and vias. In some embodiments, the second substrate 2910 may include through-vias, active devices, passive devices, and the like. The second substrate 2910 may further include conductive pads 2920 formed at the upper (shown) and lower (not shown) surfaces of the second substrate 2910.

The first external connectors 2970 may be aligned with corresponding conductive connections on the second substrate 2910 opposite the interposer 2940 and singulated SoIC package 2700. Once aligned the first external connectors 2970 may then be reflowed in order to bond the second substrate 2910 to the interposer 2940. However, any suitable bonding process may be used to connect the interposer 2940 to the second substrate 2910.

Second external connectors 2930 may be formed on a second side of the second substrate 2910 opposite the singulated SoIC package 2700. Second external connectors 2930 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The second external connectors 2930 may include a conductive material such as solder, copper, aluminum, gold, nickel, silver, palladium, tin, the like, or a combination thereof. In some embodiments, the second external connectors 2930 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the second external connectors 2930 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The second external connectors 2930 may be aligned with corresponding conductive connections on the second side of the substrate 2910, opposite the singulated SoIC package 2700. The second external connectors 2930 may then be subsequently reflowed in order to bond the CoWoS device 2900 to further devices. However, any suitable bonding process may be used to subsequently connect to the CoWoS device 2900.

Embodiments have been described with respect to a specific context, namely applied to a system on integrated chip (SoIC) package. However, other embodiments may also be applied to other packages and technologies. Embodiments discussed herein are to provide examples to enable making or using the subject matter of this disclosure, and a person having ordinary skill in the art will readily understand modifications that can be made while remaining within contemplated scopes of different embodiments. Like reference numbers and characters in the figures below refer to like components. Although method embodiments may be discussed as being performed in a particular order, other method embodiments may be performed in any logical order.

By utilizing the methods and processes as described above, formation of a bonding bulge and/or non-bonding between vertically stacked dies can be reduced or eliminated. Accordingly, greater yield, increased manufacturing efficiency, reduced waste, and reduced manufacturing costs can be realized.

In a first embodiment, a semiconductor device is provided, the semiconductor device including: a first die having a first substrate on a first side, external electrical connection on a second side opposite the first side, the first die having a first width; a first warpage control layer disposed on the first substrate on the first side of the first die, where the first warpage control layer adds to the first die a higher degree of rigidity than the first die has in the absence of the first warpage control layer; a second die disposed on the first warpage control layer, opposite the first die, the second die having second substrate and a second width; and a second warpage control layer disposed on the second die, opposite the first warpage control layer, where the second warpage control layer adds to the second die a higher degree of rigidity than the second die has in the absence of the second warpage control layer; and a third substrate disposed over the first die and the second die and having a third width.

In some embodiments, the second and third widths are less than the first width, and the third width is less than the second width. In some embodiments, the first warpage control layer is between 10 angstroms and 1000 angstrom thick, and the first warpage control layer is SiOₓ, SiN, SiOₓN_{y}, SiCₓ, an organic material, or a dielectric material. In some embodiments, the second warpage control layer is between 10 angstroms and 1000 angstrom thick, and the second warpage control layer is SiOₓ, SiN, SiOₓN_{y}, SiCₓ, an organic material, or a dielectric material. In some embodiments, the semiconductor further includes: a first bonding layer disposed over the second warpage control layer, opposite the second die; and a second bonding layer on a first side of the third substrate closest to the second die. In some embodiments, sidewalls of the first die are free of the first warpage control layer, and sidewalls of the second die are free of the second warpage control layer. In some embodiments, the semiconductor device further includes a plurality of second dies disposed over the first die.

In a second embodiments, a method of forming a semiconductor device is provided, the method including: applying a first warpage control layer on a back side of a first die, where the first warpage control layer increases rigidity of the first die; planarizing the first warpage control layer to level the first warpage control layer within process parameters and expose metallic portions of through silicon vias (TSVs) in a substrate of the first die; forming a first bonding layer over the first warpage control layer on a side of the first warpage control layer opposite the first dies, the first bonding layer having a dielectric portion and metallization patterns electrically connecting to the TSVs of the first die; forming a second warpage control layer on a back side of a second die, where the second warpage control layer increases rigidity of the second die; bonding a front side of the second die to the first bonding layer such that the first die is electrically connected to the first die through the metallization patterns of the first bonding layer and the TSVs of the first die; and forming a set of external connectors on a front side of the first die, opposite the second die.

In some embodiments, the first warpage control layer is between 10 angstroms and 1000 angstrom thick, and where the first warpage control layer is SiOₓ, SiN, SiOₓN_{y}, SiCₓ, an organic material, or a dielectric material. In some embodiments, the second warpage control layer is between 10 angstroms and 1000 angstrom thick, and where the second warpage control layer is SiOₓ, SiN, SiOₓN_{y}, SiCₓ, an organic material, or a dielectric material. In some embodiments, the method further includes: applying a molding on and around the second die and over the first die; and removing a portion of the molding to expose the second warpage control layer on the second die and level the second warpage control layer and molding within process parameters. In some embodiments, the method further includes: arranging, before applying the molding on and around the second die and over the first die, a dummy chip on the first warpage control layer opposite the first die and on a same side as the second die, where applying the molding on and around the second die and over the first die further includes applying the molding on and around the dummy chip. In some embodiments, the first warpage control layer encapsulates a portion, less than an entire length, of a sidewall of the first die. In some embodiments, the second warpage control layer does not encapsulate any portion of a sidewall of the second die.

In a third embodiment, a semiconductor device is provided, the semiconductor device including: a first die having a plurality of external electrical connections on a first side; a first warpage control layer disposed on a second side of the first die opposite the first side, where the first warpage control layer limits curvature of the first die while the first die is unsupported on the first side; a second die disposed on a first side on the first warpage control layer opposite the first die, where the second die is electrically connected to the first die; and a second warpage control layer disposed on a second side of the second die opposite the first side, where the second warpage control layer limits curvature of the second die while the second die is unsupported on the first side.

In some embodiments, the semiconductor device further including a molding film encapsulating sidewalls of the second die and over the first die without encapsulating sidewalls of the first die. In some embodiments, the first warpage control layer and the second warpage control layer are between 10 angstroms and 1000 angstrom thick, and where the first warpage control layer and the second warpage control layer are SiOₓ, SiN, SiOₓN_{y}, SiCₓ, an organic material, or a dielectric material. In some embodiments, at least one of the first warpage control layer or the second warpage control layer are a composite film including two or more layers selecting from the group consisting of SiOₓ, SiN, SiOₓN_{y}, SiCₓ, an organic material, and a dielectric material. In some embodiments, a first portion, less than an entire length, of a sidewall of the first die are encapsulated by the first warpage control layer, and a second portion, less than an entire length, of a sidewall of the second die are encapsulated by the second warpage control layer. In some embodiments, a dummy chip is arranged on the first warpage control layer on a same side as the second die and on a side of the first warpage control layer opposite the first die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first die having a first substrate on a first side, external electrical connection on a second side opposite the first side, the first die having a first width;
a first warpage control layer disposed on the first substrate on the first side of the first die, wherein the first warpage control layer adds to the first die a higher degree of rigidity than the first die has in the absence of the first warpage control layer;
a second die disposed on the first warpage control layer, opposite the first die, the second die having second substrate and a second width; and
a second warpage control layer disposed on the second die, opposite the first warpage control layer, wherein the second warpage control layer adds to the second die a higher degree of rigidity than the second die has in the absence of the second warpage control layer; and
a third substrate disposed over the first die and the second die and having a third width.

2. The semiconductor device of claim 1, wherein the second and first widths are less than the third width, and the second width is less than the first width.

3. The semiconductor device of claim 1, wherein the first warpage control layer is between 10 angstroms and 1000 angstrom thick, and wherein the first warpage control layer is SiOₓ, SiN, SiOₓN_{y}, SiCₓ, an organic material, or a dielectric material.

4. The semiconductor device of claim 1, wherein the second warpage control layer is between 10 angstroms and 1000 angstrom thick, and wherein the second warpage control layer is SiOₓ, SiN, SiOₓN_{y}, SiCₓ, an organic material, or a dielectric material.

5. The semiconductor device of claim 1, further comprising:
a first bonding layer disposed over the second warpage control layer, opposite the second die; and
a second bonding layer on a first side of the third substrate closest to the second die.

6. The semiconductor device of claim 5, wherein sidewalls of the first die are free of the first warpage control layer, and wherein sidewalls of the second die are free of the second warpage control layer.

7. The semiconductor device of claim 1, further comprising a plurality of second dies disposed over the first die.

8. A method of forming a semiconductor device, comprising:
applying a first warpage control layer on a back side of a first die, wherein the first warpage control layer increases rigidity of the first die;
planarizing the first warpage control layer to level the first warpage control layer within process parameters and expose metallic portions of through silicon vias (TSVs) in a substrate of the first die;
forming a first bonding layer over the first warpage control layer on a side of the first warpage control layer opposite the first dies, the first bonding layer having a dielectric portion and metallization patterns electrically connecting to the TSVs of the first die;
forming a second warpage control layer on a back side of a second die, wherein the second warpage control layer increases rigidity of the second die;
bonding a front side of the second die to the first bonding layer such that the second die is electrically connected to the first die through the metallization patterns of the first bonding layer and the TSVs of the first die; and
forming a set of external connectors on a front side of the first die, opposite the second die.

9. The method of forming the semiconductor device of claim 8, wherein the first warpage control layer is between 10 angstroms and 1000 angstrom thick, and wherein the first warpage control layer is SiOₓ, SiN, SiOₓN_{y}, SiCₓ, an organic material, or a dielectric material.

10. The method of forming the semiconductor device of claim 8, wherein the second warpage control layer is between 10 angstroms and 1000 angstrom thick, and wherein the second warpage control layer is SiOₓ, SiN, SiOₓN_{y}, SiCₓ, an organic material, or a dielectric material.

11. The method of forming the semiconductor device of claim 8, further comprising:
applying a molding on and around the second die and over the first die; and
removing a portion of the molding to expose the second warpage control layer on the second die and level the second warpage control layer and molding within process parameters.

12. The method of forming the semiconductor device of claim 11, further comprising:
arranging, before applying the molding on and around the second die and over the first die, a dummy chip on the first warpage control layer opposite the first die and on a same side as the second die;
wherein applying the molding on and around the second die and over the first die further comprises applying the molding on and around the dummy chip.

13. The method of forming the semiconductor device of claim 8, wherein the first warpage control layer encapsulates a portion, less than an entire length, of a sidewall of the first die.

14. The method of forming the semiconductor device of claim 8, wherein the second warpage control layer does not encapsulate any portion of a sidewall of the second die.

15. A semiconductor device, comprising:
a first die having a plurality of external electrical connections on a first side;
a first warpage control layer disposed on a second side of the first die opposite the first side, wherein the first warpage control layer limits curvature of the first die while the first die is unsupported on the first side;
a second die disposed on a first side on the first warpage control layer opposite the first die, wherein the second die is electrically connected to the first die; and
a second warpage control layer disposed on a second side of the second die opposite the first side, wherein the second warpage control layer limits curvature of the second die while the second die is unsupported on the first side.

16. The semiconductor device of claim 15, further comprising a molding film encapsulating sidewalls of the second die and over the first die without encapsulating sidewalls of the first die.

17. The semiconductor device of claim 15, wherein the first warpage control layer and the second warpage control layer are between 10 angstroms and 1000 angstrom thick, and wherein the first warpage control layer and the second warpage control layer are SiOₓ, SiN, SiOₓN_{y}, SiCₓ, an organic material, or a dielectric material.

18. The semiconductor device of claim 17, wherein at least one of the first warpage control layer or the second warpage control layer are a composite film comprising two or more layers selecting from the group consisting of SiOₓ, SiN, SiOₓN_{y}, SiCₓ, an organic material, and a dielectric material.

19. The semiconductor device of claim 15, wherein a first portion, less than an entire length, of a sidewall of the first die are encapsulated by the first warpage control layer, and a second portion, less than an entire length, of a sidewall of the second die are encapsulated by the second warpage control layer.

20. The semiconductor device of claim 15, wherein a dummy chip is arranged on the first warpage control layer on a same side as the second die and on a side of the first warpage control layer opposite the first die.
